(19) United States
(12) Patent Application Publication
(10) Pub. No.: US 2025/0056798 A1
(43) Pub. Date: Feb. 13, 2025

(54) SEMICONDUCTOR STRUCTURE AND FABRICATION METHOD THEREOF, THREE-DIMENSIONAL MEMORY

(71) Applicant: YANGTZE MEMORY TECHNOLOGIES CO., LTD., Wuhan (CN)

(72) Inventors: Shuangshuang Wu, Wuhan (CN); Zhibin Liu, Wuhan (CN); Zhong Zhang, Wuhan (CN); Di Wang, Wuhan (CN)

(21) Appl. No.: 18/531,553

(22) Filed: Dec. 6, 2023

Related U.S. Application Data
(63) Continuation of application No. PCT/CN2023/111586, filed on Aug. 7, 2023.

(51) Int. Cl. H10B 43/27; G11C 16/04; H10B 43/10; H10B 43/35

(52) U.S. Cl. CPC H10B 43/27; G11C 16/0483; H10B 43/10; H10B 43/35

(57) ABSTRACT

The present disclosure provides a semiconductor structure and a fabrication method thereof. The semiconductor structure includes a semiconductor layer, a first stack structure, a second stack structure, a gate line isolation structure, and a first dielectric layer. The first stack structure includes a plurality of first insulating layers and a plurality of gate line layers disposed alternatively. The second stack structure is disposed on a side of the first stack structure away from the semiconductor layer and includes a select gate line layer. The gate line isolation structure penetrates through the first stack structure and the second stack structure in a direction perpendicular to the semiconductor layer. The first dielectric layer is disposed on a side of the second stack structure away from the semiconductor layer, contacts the gate line isolation structure, and covers at least a part of a surface of the gate line isolation structure away from the semiconductor layer.

### CROSS-REFERENCE TO RELATED APPLICATIONS

The present application is a continuation of International Application No. PCT/CN2023/111586, filed on Aug. 7, 2023, the content of which is incorporated herein by reference in its entirety.

### TECHNICAL FIELD

The present disclosure relates to semiconductor chip field, particularly relates to a semiconductor structure and a fabrication method thereof, a three-dimensional memory, a memory system and an electronic apparatus.

### BACKGROUND

As the feature sizes of memory cells approach the lower limit of process, planar process and manufacturing techniques have become challenging and expensive, resulting in 2D or planar Not-And (NAND) flashes with storage density approaching the upper limit. In order to overcome limitations on 2D or planar NAND flashes, memories with three-dimensional structure (3D NAND) have been developed in the industry, which improve the storage density by arranging memory cells on the semiconductor layer in three dimensions.

### SUMMARY

According to one aspect of the present disclosure, a semiconductor structure is provided. The semiconductor structure may include a semiconductor layer. The semiconductor structure may include a first stack structure disposed on the semiconductor layer and including a plurality of first insulating layers and a plurality of gate line layers disposed alternatively. The semiconductor structure may include a second stack structure disposed on a side of the first stack structure away from the semiconductor layer and including at least one select gate line layer. The semiconductor structure may include a gate line isolation structure penetrating through the first stack structure and the second stack structure in a direction perpendicular to the semiconductor layer. The semiconductor structure may include a first dielectric layer disposed on a side of the second stack structure away from the semiconductor layer and in contact with the gate line isolation structure. The first dielectric layer may cover at least part of a surface of the gate line isolation structure away from the semiconductor layer.

In some implementations, the semiconductor structure may include a first channel structure penetrating through the first stack structure. In some implementations, the semiconductor structure may include a second channel structure penetrating through the second stack structure and connected with the first channel structure. In some implementations, the semiconductor structure may include a second dielectric layer disposed on a side of the first dielectric layer away from the semiconductor layer. In some implementations, the semiconductor structure may include a first conductive post penetrating through the second dielectric layer and the first dielectric layer and connected with the second channel structure.

In some implementations, the semiconductor structure may include a storage region. In some implementations, the semiconductor structure may include a connection region. In some implementations, the gate line isolation structure may include a first part located in the storage region. In some implementations, the first dielectric layer may be located in the storage region, the first dielectric layer is in contact with the first part, and the first dielectric layer covers a surface of the first part away from the semiconductor layer.

In some implementations, the semiconductor structure may include a second conductive post located in the connection region. In some implementations, the second conductive post may penetrate through the second dielectric layer, the second stack structure, and a part of the first stack structure. In some implementations, the second conductive post may be connected with the gate line layer.

In some implementations, the semiconductor structure may include a third conductive post penetrating through the second dielectric layer and the first dielectric layer, the third conductive post being connected with the select gate line layer. In some implementations, the first dielectric layer surrounds the third conductive post and is in contact with the third conductive post. In some implementations, there may be a first spacing between the first dielectric layer and the third conductive post with a part of the second dielectric layer filled in the first spacing.

In some implementations, the semiconductor structure may include a storage region. In some implementations, the semiconductor structure may include a connection region. In some implementations, the first dielectric layer may be located in the storage region and the connection region. In some implementations, the first dielectric layer may cover a surface of the gate line isolation structure away from the semiconductor layer.

In some implementations, the semiconductor structure may include a second conductive post located in the connection region. In some implementations, the second conductive post may penetrate through the second dielectric layer, the first dielectric layer, the second stack structure, and a part of the first stack structure. In some implementations, the second conductive post may be connected with the gate line layer. In some implementations, the first dielectric layer may further surround the second conductive post and may be in contact with the second conductive post.

In some implementations, the semiconductor structure may include a third conductive post penetrating through the second dielectric layer and the first dielectric layer and connected with the select gate line layer. In some implementations, the first dielectric layer may surround the third conductive post and is in contact with the third conductive post.

In some implementations, the first dielectric layer and the second dielectric layer may have different etch selection ratios under same etch conditions.

In some implementations, a sidewall of the gate line isolation structure may be in contact with the select gate lines.

In some implementations, the second stack structure may further include a third dielectric layer disposed between the select gate line layer and the first dielectric layer and having a etch selection ratio different from that of the first dielectric layer under same etch conditions.

According to another aspect of the present disclosure, a method of fabricating a semiconductor structure is provided. The method may include forming a first stack structure and a second stack structure on a substrate. The first stack structure may include a plurality of first insulating layers and a plurality of gate line layers disposed alternatively. The second stack structure may include at least one select gate line layer. The method may include forming a gate line isolation structure penetrating through the first stack structure and the second stack structure. The method may include forming an initial first dielectric layer on sides of the second stack structure and the gate line isolation structure away from the substrate. The initial first dielectric layer may cover surfaces of the second stack structure and the gate line isolation structure away from the substrate.

In some implementations, the semiconductor structure may include a storage region and a connection region. In some implementations, the initial first dielectric layer may include a third part located in the storage region and a fourth part located in the connection region. In some implementations, after the forming the initial first dielectric layer, the method may further include patterning the initial first dielectric layer to remove the fourth part of the initial first dielectric layer. In some implementations, after the forming the initial first dielectric layer, the method may further include forming a first avoiding hole in the third part of the initial first dielectric layer with a spacing between the first avoiding hole and the gate line isolation structure.

In some implementations, before the forming the gate line isolation structure, the method may further include forming a first channel structure penetrating through the first stack structure and a second channel structure penetrating the second stack structure and connected with the first channel structure. In some implementations, after the patterning the initial first dielectric layer, the method may further include forming a second dielectric layer on sides of the initial first dielectric layer and the second stack structure away from the substrate. In some implementations, after the patterning the initial first dielectric layer, the method may further include forming a first contact hole on the second dielectric layer, the first contact hole penetrating through the second dielectric layer and stopping at the third part of the initial first dielectric layer. In some implementations, after the patterning the initial first dielectric layer, the method may further include extending the first contact hole such that the first contact hole penetrates through the initial first dielectric layer and exposes a surface of the second channel structure away from the substrate. In some implementations, after the patterning the initial first dielectric layer, the method may further include forming a first conductive post in the first contact hole, the first conductive post being connected with the second channel structure.

In some implementations, at the same time as forming the first contact hole on the second dielectric layer, the method may further include forming a second contact hole and a third contact hole. In some implementations, the second contact hole may be located in the connection region. In some implementations, the second contact hole may penetrate through the second dielectric layer, the second stack structure, and a part of the first stack structure. In some implementations, the second contact hole may expose one of the gate line layers. In some implementations, the third contact hole may penetrate through the second dielectric layer and the first avoiding hole and expose a part of the select gate line layer. In some implementations, at the same time as forming the first conductive post in the first contact hole, the method may further include forming a second conductive post in the second contact hole and forming a third conductive post in the third contact hole. In some implementations, the second conductive post may be connected with the gate line layer. In some implementations, the third conductive post may be connected with the select gate line layer.

In some implementations, between the extending the first contact hole such that the first contact hole penetrates through the initial first dielectric layer and forming the first conductive post in the first contact hole, the method may further include forming a second contact hole and a third contact hole synchronously. In some implementations, the second contact hole may be located in the connection region. In some implementations, the second contact hole may penetrate through the second dielectric layer, the second stack structure, and a part of the first stack structure. In some implementations, the second contact hole may expose one of the gate line layers. In some implementations, the third contact hole may penetrate through the second dielectric layer and the first avoiding hole. In some implementations, the third contact hole may expose the select gate line layer. In some implementations, between the extending the first contact hole such that the first contact hole penetrates through the initial first dielectric layer and forming the first conductive post in the first contact hole, the method may further include forming a second conductive post in the second contact hole and forming a third conductive post in the third contact hole. In some implementations, the second conductive post being connected with the gate line layer. In some implementations, the third conductive post may be connected with the select gate line layer.

In some implementations, after the forming the initial first dielectric layer, the method may further include forming a second dielectric layer on a side of the initial first dielectric layer away from the substrate. In some implementations, after the forming the initial first dielectric layer, the method may further include forming a first contact hole on the second dielectric layer, the first contact hole penetrating through the second dielectric layer and stopping at the initial first dielectric layer. In some implementations, after the forming the initial first dielectric layer, the method may further include extending the first contact hole such that the first contact hole penetrates through the initial first dielectric layer and exposes a surface of the second channel structure away from the substrate. In some implementations, after the forming the initial first dielectric layer, the method may further include forming a first conductive post in the first contact hole, the first conductive post being connected with the second channel structure.

In some implementations, between the extending the first contact hole and forming the first conductive post in the first contact hole, the method may further include forming a third contact hole that penetrates through the second dielectric layer and the initial first dielectric layer and exposes the select gate line layer. In some implementations, between the extending the first contact hole and forming the first conductive post in the first contact hole, the method may further include forming a second contact hole. In some implementations, the second contact hole may be located in the connection region, penetrate through the second dielectric layer, the initial first dielectric layer, the second stack structure, and a part of the first stack structure, and exposes one of the gate line layers. In some implementations, an order of the forming the third contact hole and the forming the second contact hole may be interchangeable.

In some implementations, between the extending the first contact hole and forming the first conductive post in the first contact hole, the method may further include forming a second contact hole and a third contact hole at a same time. In some implementations, the second contact hole may be located in the connection region. In some implementations, the second contact hole may penetrate through the second dielectric layer, the initial first dielectric layer, the second stack structure, and a part of the first stack structure. In some implementations, the second contact hole may expose one of the gate line layers. In some implementations, the third contact hole may penetrate through the second dielectric layer and the first avoiding hole. In some implementations, the third contact hole may expose a part of the select gate line layer.

According to a further aspect of the present disclosure, a three-dimensional memory is provided. The three-dimensional memory may include a semiconductor structure. The semiconductor structure may include a semiconductor layer. The semiconductor structure may include a first stack structure disposed on the semiconductor layer and including a plurality of first insulating layers and a plurality of gate line layers disposed alternatively. The semiconductor structure may include a second stack structure disposed on a side of the first stack structure away from the semiconductor layer and including at least one select gate line layer. The semiconductor structure may include a gate line isolation structure penetrating through the first stack structure and the second stack structure in a direction perpendicular to the semiconductor layer. The semiconductor structure may include a first dielectric layer disposed on a side of the second stack structure away from the semiconductor layer and in contact with the gate line isolation structure. The first dielectric layer may cover at least part of a surface of the gate line isolation structure away from the semiconductor layer. The three-dimensional memory may include a peripheral device connected with the semiconductor structure.

### BRIEF DESCRIPTION OF DRAWINGS

In order to illustrate technical solutions in the present disclosure more clearly, drawings needed in the description of the some implementations of the present disclosure will be briefly introduced. The drawings provided in the present disclosure are drawings of only some implementations of present disclosure. Furthermore, the accompanying drawings described below may be regarded as illustrative diagrams rather than limiting the practical sizes of products, practical flows of methods and practical timings of signals involved in implementations of the present disclosure.

FIG. 1 is a sectional structure diagram of a semiconductor structure, according to some implementations.

FIG. 2 is a sectional structure diagram of a semiconductor structure, according to some implementations.

FIG. 3 is a structure diagram of a memory cell string of the semiconductor structure shown in FIG. 2, according to some implementations.

FIG. 4 is an equivalent circuit diagram of a memory cell string, according to some implementations.

FIG. 5 is a plane structure diagram of a semiconductor structure, according to some implementations.

FIG. 6 is another sectional structure diagram of a semiconductor structure, according to some implementations.

FIG. 7 is yet another sectional structure diagram of a semiconductor structure, according to some implementations.

FIG. 8 is another plane structure diagram of a semiconductor structure, according to some implementations.

FIG. 9A and FIG. 9B are yet another sectional structure diagrams of a semiconductor structure, according to some implementations.

FIGS. 10A-10C are flow charts of a fabrication method of a semiconductor structure, according to some implementations.

FIGS. 11-30 are operation diagrams of fabrication of a semiconductor structure, according to some implementations.

FIGS. 31A and 31B are structure diagrams of a three-dimensional memory, according to some implementations.

FIG. 32 is a block diagram of a memory system, according to some implementations.

FIG. 33 is a block diagram of a memory system, according to some other implementations.

### DETAILED DESCRIPTION

The technical solution in some implementations of the present disclosure will be described in detail below with reference to accompanying drawings. However, it is obvious that the described implementations are only a part of rather than all implementations of the present disclosure. All other implementations obtained by one of ordinary skill in the art based on implementations provided in the present disclosure fall within the scope of the present disclosure.

In the description of the present disclosure, it is to be understood that terms “center”, “on”, “under”, “front”, “back”, “left”, “right”, “vertical”, “horizontal”, “top”, “bottom”, “inside”, “outside” etc. refer to the azimuth or position relationship based on what is shown in figures, which are only for the purpose of facilitating describing the present disclosure and simplifying description rather than indicating or implying that the mentioned devices or elements must have certain azimuth, must be constructed and operated in certain azimuth, and therefore are not constructed as limiting the present disclosure.

Unless otherwise stated in context, the term “include” will be interpreted in an open and containing sense, namely “comprise but not limited to” throughout the description and claims. In the description of the specification, the terms “one implementation”, “some implementations”, “example implementation”, “as an example” or “some examples” are intended to mean that specific features, structures, materials, or characteristics related to the implementations or examples are included in at least one implementation or example of the present disclosure. The illustrative representation of the above terms does not necessarily refer to the same implementation or example. Furthermore, the particular features, structures, materials or characteristics may be included in any suitable way in any one or more implementations or examples.

As used herein, terms such as “first”, “second”, etc. are only used for description rather than being interpreted as indicating or implying relative importance or implicitly indicating the number of the referenced technical features. Therefore, a feature qualified by “first” or “second” may include explicitly or implicitly one or more instances of the feature. In the description of the implementations of the present disclosure, “a plurality of” means two or more unless otherwise specified.

While describing some implementations, expressions such as “couple” and “connect” as well as their extensions might be used. For example, the term “connect” may be used while describing some implementations to indicate that two or more components have direct physical contact or electrical contact. As another example, the term “couple” may be used while describing some implementations to indicate that two or more components have direct physical contact or electrical contact. However, the term “couple” may also indicate there is no direct contact between two or more components, but they still cooperate or interact with each other. Implementations disclosed herein are not necessarily limited to the contents provided herein.

“At least one of A, B and C” and “at least one of A, B or C” have the same meaning and both include the following combinations of A, B and C: only A; only B; only C; a combination of A and B; a combination of A and C; a combination of B and C; and a combination of A, B and C.

“A and/or B” includes the following three combinations: only A, only B and a combination of A and B.

The use of “configured to” herein implies open and inclusive wording but not excluding apparatuses adapted to or configured to execute additional tasks or operations.

In addition, the use of “based on” implies open and inclusive wording, since a process, an operation, a computation, or other acts “based on” one or more of the conditions or values may be based on additional conditions or values other than said value in practice.

As used herein, “about”, “generally”, or “approximately” includes the stated value and the average value in the acceptable deviation range of a certain value, wherein said acceptable deviation range is determined by those of ordinary skill in the art considering the measurements under discussion and errors, namely limitations of the measurement system, related to measurements of a certain quantity.

In contents of the present disclosure, the meanings of “on”, “over”, and “above” should be interpreted in the broadest manner such that “on” not only means “directly on” something but also includes the meaning of “on” something with an intermediate feature or a layer therebetween, and that “over” or “above” not only means “over” or “above” something but can also include the meaning it is “above” or “over” something with no intermediate feature or layer therebetween (i.e., directly on something).

Example implementations are described herein with reference to at least one of sectional views or plan views as ideal illustrative drawings. In the drawings, thicknesses of layers and regions are exaggerated for clear illustration. Therefore, it is possible to envision shape variations with respect to drawings due to, for example, at least one of manufacturing techniques or tolerances. Accordingly, example implementations should not be interpreted as limiting the shapes of regions shown herein, but including shape deviations caused by, for example, manufacturing. For example, an etched region shown as rectangular generally has curved features. Therefore, regions shown in drawings are illustrative in nature, and their shapes are not intended to show practical shapes of regions of a device and not intended to limit the scope of example implementations.

As used herein, the term “substrate” refers to a material on which subsequent material layers may be added. The substrate may be patterned itself. Materials added on the substrate may be patterned or may remain unpatterned. Furthermore, the substrate may include a plurality of semiconductor materials such as silicon, germanium, gallium arsenide, and indium phosphide. Alternatively, the substrate may be made of non-conductive materials such as glass, plastics or sapphire wafer.

The term “three-dimensional memory” refers to a semiconductor device formed by memory cell transistor strings (herein, referred to “memory cell strings”, such as NAND memory cell strings) that are arranged in an array on the main surface of the semiconductor layer or source layer and extending in the direction perpendicular to the semiconductor layer or the source layer. As used herein, the term “vertical/vertically” means nominally perpendicular to the main surface (namely the lateral surface) of the semiconductor layer or the source layer.

As shown in FIG. 1, a select gate line layer 01, a stop layer 02, a first conductive post 03, and a gate line isolation structure 04 are disposed in the semiconductor structure. In the fabrication process of the semiconductor structure, the first conductive post 03 is formed first, and then the gate line isolation structure 04 is fabricated. In order to prevent the etching solution from etching the stop layer 02 in the process of forming the gate line isolation structure 04, it may be beneficial to provide an opening 05 in the stop layer 02 and form the gate line isolation structure 04 in the opening 05 with a first spacing L1 from a sidewall of the opening 05. On the one hand, the above-described fabrication process of a semiconductor structure has an undesirable number of operations, which impedes a reduction of semiconductor structure fabrication costs and an further impedes an improvement of fabrication efficiency of the semiconductor structure. On the other hand, due to the size error and process error of the opening 05 (such as the dis-alignment error between the gate line isolation structure 04 and the opening 05), the gate line isolation structure 04 may be connected with the stop layer 02, and the stop layer 02 between the first conductive post 03 and the gate line isolation structure may be etched away. This may cause the first conductive post 03 that is formed to come into contact with the select gate line layer 01 and the gate line isolation structure 04, resulting in a defective semiconductor structure.

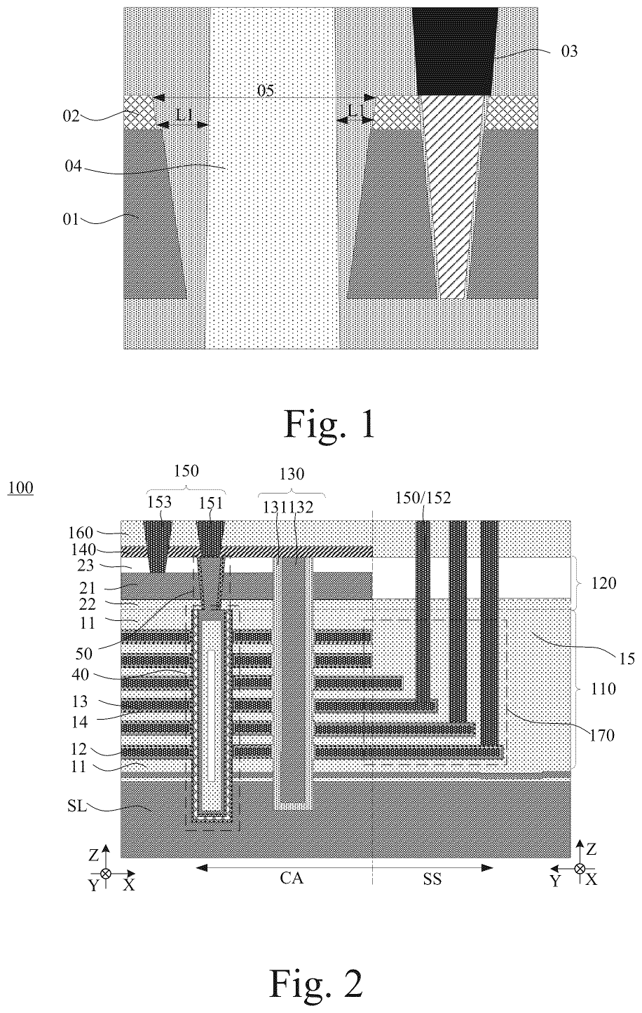

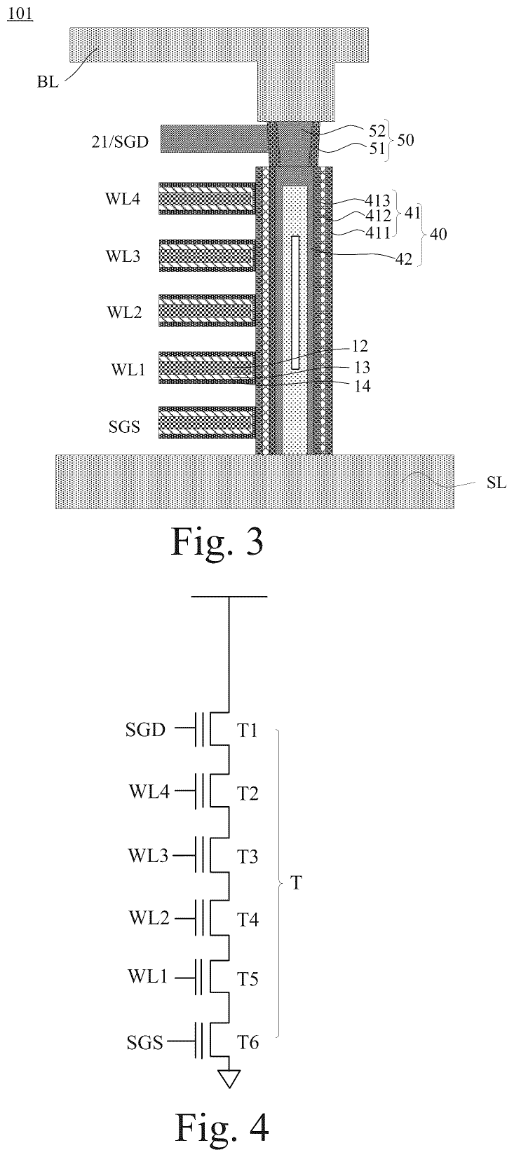

FIG. 2 is a sectional diagram of a semiconductor structure provided in some implementations of the present disclosure. FIG. 3 is a sectional diagram of a memory cell string of the semiconductor structure shown in FIG. 2. FIG. 4 is an equivalent circuit diagram of a memory cell string shown in FIG. 3.

As used in the present application, whether a component is “on”, “over”, or “under” another component (e.g., layer, structure, or device) in the semiconductor structure is determined with respect to the semiconductor layer SL of the semiconductor structure 100 in the third direction Z while the semiconductor layer SL is located in the bottom plane of the semiconductor structure 100 in the third direction Z. In the entire disclosure, the same or similar concepts are applied to describe spatial relationships.

Referring to FIG. 2, in order to illustrate the structure of the semiconductor structure more clearly, the view of storage region CA and the view of connection region SS are depicted. As shown in FIG. 2, the view of the storage region CA is based on the left coordinate system, and the view of the connection region SS is based on the right coordinate system. That is, the view of the storage region CA shows the sectional structure of the storage region CA of the semiconductor structure in the X direction (first direction), and the view of the connection region SS shows the sectional structure of the connection region SS of the semiconductor structure in the Y direction.

According to some implementations of the present disclosure provide a semiconductor structure 100 is provided. Referring to FIGS. 2, 3, and 4, the semiconductor structure 100 includes a semiconductor layer SL, a first stack structure 110, a second stack structure 120, a gate line isolation structure 130, and a first dielectric layer 140, as well as a plurality of conductive posts 150.

By way of example and not limitation, the material for the above-described semiconductor layer SL may include semiconductor material such as single crystalline silicon, poly-crystalline silicon, single crystalline germanium, III-V compound semiconductor material, II-VI compound semiconductor, and/or other suitable semiconductor materials. The semiconductor layer SL may be partially or completely doped. For example, the semiconductor layer SL may include a doped region doped with P-type dopant. The semiconductor layer SL may further include a non-doped region.

The first stack structure 110 may include a plurality of first insulating layers 11 and a plurality of gate line layers 12 disposed alternatively.

By way of example and not limitation, the material for the first insulating layer 11 is an insulation material that may include at least one of silicon oxide (silicon dioxide), silicon nitride, silicon oxynitride, doped silicon oxide, organic silicate glass, dielectric metallic oxide (e.g., such as aluminum oxide, hafnium dioxide, and silicate(s) thereof), and organic insulating materials, just to name a few. The material for the gate line layers 12 may be a conductive material such as one of tungsten, cobalt, copper, aluminum and metal silicide or a combination thereof. For example, the material for the first insulating layers 11 may be silicon oxide, and the material for the gate line layers 12 may be tungsten.

In some implementations, as shown in FIGS. 2 and 3, there may also be a metal compound layer 13 and a fourth dielectric layer 14 between the first insulating layers 11 and the gate line layers 12. The metal compound layer 13 covers the gate line layer 12. The metal compound layer 13 may be configured to improve the adhesion between the gate line layers 12 and the first insulating layers 11. In some non-limiting examples, the material for the metal compound layer 13 includes at least one of, e.g., titanium nitride, tantalum nitride, and tungsten carbide.

The fourth dielectric layer 14 covers the metal compound layer 13 and may be configured to reduce the risk of charges in the first channel structure 40 flowing to the gate line layers 12. In some non-limiting examples, the material for the fourth dielectric layer 14 may be a material having high dielectric constant. For example, the material for the fourth dielectric layer 14 includes at least one of, e.g., aluminum oxide, hafnium oxide, and tantalum oxide.

In some implementations, one first insulating layer 11 and one gate line layer 12 on the upper surface of the first insulating layers 11 may constitute a layer pair. The number of the layer pairs included in the first stack structure 110 is not limited. By way of example and not limitation, the first stack structure 110 may include, e.g., 16, 32, 64, 128 layer pairs, etc.

As shown in FIGS. 2 and 3, the semiconductor structure 100 may further include a first channel structure 40 that penetrates through the first stack structure 110 in a direction Z perpendicular to the semiconductor layer SL and extends into the semiconductor layer SL. By way of example and not limitation, the first channel structure 40 may be configured to form memory cells of the memory cell string 101 and store data.

The first channel structure 40 may include a storage function layer 41 and a first channel layer 42 disposed in turn. The storage function layer 41 may include a barrier layer 411, a charge trapping layer 412 and a tunneling layer 413. The charge trapping layer 412 may be configured to store charges. The barrier layer 411 may be configured to block charges stored in the charge trapping layer 412 and provide electric insulation between the charge trapping layer 412 and the gate line layers 12. The tunneling layer 413 may be configured to generate charges (electrons or holes). By way of example and not limitation, the material for the barrier layer 411 may include, but is not limited to, silicon oxide; the material for the charge trapping layer 412 may include, but is not limited to, silicon nitride; and the material for the tunneling layer 413 may include, but is not limited to, silicon oxide. The first channel layer 42 may be configured to transfer the required charges. The material for the first channel layer 42 may include, but is not limited to, doped polysilicon.

The first channel structure 40 and the gate line layers 12 in the first stack structure 110 together constitute a memory cell. By way of example and not limitation, as shown in FIGS. 3 and 4, the gate line layers 12 and the first channel structure 40 form a plurality of memory transistors T. One memory transistor T (such as T2-T5 shown in FIG. 4) may be set as a memory cell. One memory transistor T may be formed by the first channel layer 42 and a gate line layer 12 surrounding the first channel layer 42.

In some implementations, the gate line layer 12 of the transistor (T6 in FIG. 4) of the plurality of memory transistors T that is at the bottom (closest to the semiconductor layer SL) may be constructed as a source end select gate SGS. The source end select gate SGS may be configured to control the conduction state of the transistor T6 and, in turn, to control the conduction state of the source end channel in the memory cell string 101.

The second stack structure 120 may include at least one select gate line layer 21 that is configured to form the drain end select gate SGD of the memory cell string 101. The drain end select gate SGD may be configured to control the conduction state of the switching transistor Tl and, in turn, to control the conduction state of the drain end channel in the memory cell string 101. The select gate line layer 21 may be a top select gate (TSG).

In some implementations, an example is described in which the second stack structure 120 includes one select gate line layer 21. Of course, the second stack structure 120 may also include two, three, or more layers of select gate line layers 21, in accordance with examples of the present disclosure.

The material for the select gate line layer 21 may be a conductive material and the material for the select gate line layer 21 may be the same as the material for the gate line layer 12. For example, the material for the select gate line layer 21 and the material for the gate line layer 12 may be tungsten. Alternatively, the material for the select gate line layer 21 and the material for the gate line layer 12 are different. The material for the select gate line layer 21 may include, but is not limited to, polysilicon or germanium silicon.

By way of example and not limitation, there may be one second insulating layer 22 between the select gate line layer 21 and the first stack structure 110. The material for the second insulating layer 22 and the material for the first insulating layer 11 may be the same. The first insulating layer 11 and the second insulating layer 22 on the top layer may be fabricated separately with two processes. However, since the materials for both are the same, there may not be any obvious boundary between them. In FIG. 2, in order to distinguish the first insulating layer 11 and the second insulating layer 22 on the top layer, a dashed line is drawn between the first insulating layer 11 and the second insulating layer 22 to show a distinction.

In case that the second stack structure 120 includes a plurality of select gate line layers 21, the second stack structure 120 may further include a second insulating layer (not shown) between two adjacent select gate line layers 21. By way of example and not limitation, the material for the second insulating layer and the material for the first insulating layer 11 may be the same.

In some implementations, the thickness of the select gate line layer 21 (the size in the third direction Z) may be greater than the thickness of the gate line layer 12. With such a configuration, the cross area of the select gate line layer 21 is bigger, which facilitates reducing the resistance on the select gate line layer 21 and reducing the power consumption.

The semiconductor structure 100 may further include a second channel structure 50 that penetrates through the second stack structure 120 in a direction Z perpendicular to the semiconductor layer SL.

The second channel structure 50 may include a gate dielectric layer 51 and a second channel layer 52 disposed in turn. That is, no charge storage layer and tunneling layer may be used to be provided in the second channel structure 50, which facilitates reducing the fabrication cost of the second channel structure 50 and facilitates reducing the fabrication cost of the semiconductor structure. In some implementations, the material for the gate dielectric layer 51 may include, but is not limited to, silicon oxide. The material for the second channel layer 52 may include a semiconductor material. By way of example and not limitation, the material for the second channel layer 52 may include at least one of polysilicon or single crystalline silicon.

One second channel structure 50 may be connected with one first channel structure 40. By way of example and not limitation, the second channel layer 52 of the second channel structure 50 is connected with the first channel layer 42 of the first channel structure 40. The select gate line layer 21 and the second channel structure 50 together form a switching transistor T1.

By way of example and not limitation, the semiconductor structure 100 may include a plurality of first channel structures 40 and a plurality of second channel structures 50. A side of each first channel structure 40 away from the semiconductor layer SL may be provided with a second channel structure 50. The second channel layer 52 of a second channel structure 50 may be connected with the first channel layer 42 of the corresponding first channel structure 40.

The gate line isolation structure 130 may penetrate through the first stack structure 110 and the second stack structure 120 in a direction Z perpendicular to the semiconductor layer SL. By way of example and not limitation, the lower end of the gate line isolation structure 130 extends into the semiconductor layer SL and does not penetrate through the semiconductor layer SL. The gate line isolation structure 130 may be configured to separate the gate line layer 12 into a plurality of gate lines and separate the select gate line layer 21 into a plurality of select gate lines.

In some implementations, the material for the gate line isolation structure 130 may include an insulating material. By way of example and not limitation, the insulating material may include, but is not limited to, silicon oxides, etc. The gate line isolation structure 130 may further include two layers of different materials. As shown in FIG. 2, the gate line isolation structure 130 may include a third insulating layer 131 and an intermediate filling layer 132 to provide mechanical support.

The first dielectric layer 140 is disposed on sides of the second stack structure 120 and the gate line isolation structure 130 away from the semiconductor layer SL. The first dielectric layer 140 contacts the gate line isolation structure 130 and covers at least part of the surface of the gate line isolation structure 130 away from the semiconductor layer SL. That is, the first dielectric layer 140 may be located at least in part directly above the gate line isolation structure 130 and contacts the upper surface of the gate line isolation structure 130. Based on this, in the fabrication process of the semiconductor structure 100, it may be possible to fabricate the gate line isolation structure 130 first, and then form the first dielectric layer 140 and the subsequent conductive posts 150. In this way, it may be possible to prevent the etching solution from etching the first dielectric layer 140 in the process of forming the gate line isolation structure 130, and to reduce the risk that the first conductive posts 151 contact the select gate line layer 21 and the gate line isolation structure 130. It may be further possible to simplify the fabrication process of the semiconductor structure 100, increase the fabrication efficiency of the semiconductor structure 100, and, in turn, reduce the fabrication cost of the semiconductor structure 100.

In some implementations, as shown in FIG. 2, the semiconductor structure 100 may further include a second dielectric layer 160 and a first conductive post 151. The second dielectric layer 160 may be disposed on a side of the first dielectric layer 140 away from the semiconductor layer SL. The first conductive post 151 penetrates through the second dielectric layer 160 and the first dielectric layer 140 and is connected with the second channel structure 50. For example, the first conductive post 151 may be connected with the second channel layer 52 of the second channel structure 50. The first conductive post 151 may be configured to lead out the second channel layer 52 of the second channel structure 50, thereby facilitating transferring electrical signals to the second channel layer 52 of the second channel structure 50, and, in turn, transferring electrical signals to the first channel layer 42.

In some implementations, the first dielectric layer 140 may serve as the etch stop layer in the process of fabricating the first conductive post 151. Based on this, the etch selection ratios of the first dielectric layer 140 and the second dielectric layer 160 under the same etch conditions may be different. Thus, in the process of forming the first contact hole of the first conductive post 151 by etching, it may be possible to make the first contact hole to stop at the interface between the first dielectric layer 140 and the second dielectric layer 160. By way of example and not limitation, the material for the first dielectric layer 140 and the material for the second dielectric layer 160 may be different. For example, the material for the first dielectric layer 140 may be silicon nitride, and the material for the second dielectric layer 160 may be silicon oxide.

In some implementations, the second stack structure 120 may further include a third dielectric layer 23. The third dielectric layer 23 may be disposed between the select gate line layer 21 and the first dielectric layer 140. The third dielectric layer 23 may be configured to protect the select gate line layer 21 to avoid wear-out of the select gate line layer 21 and allow the second stack structure 120 to have a relatively planar upper surface, which facilitates subsequently forming the select gate line layer 21 and the first dielectric layer 140.

The third dielectric layer 23 and the first dielectric layer 140 may have different selection ratios under the same etching conditions. It may be possible to reduce the risk of etching the third dielectric layer 23 around the second channel structure 50 in the process of etching the first dielectric layer 140, which in turn reduces the risk of direct contact between the first conductive post 151 and the select gate line layer 21.

In some implementations, referring to FIG. 2, the sidewall of the gate line isolation structure 130 may contact the select gate line layer 21. Since the gate line isolation structure 130 is formed before the first conductive post 151, it may be not necessary to dispose openings for avoiding the gate line isolation structure 130 on the first dielectric layer 140 and the select gate line layer 21 in advance. Therefore, it may be possible to fabricate the gate line isolation structure 130 directly, which facilitates simplifying the fabrication process of the semiconductor structure 100 and reducing the fabrication cost of the semiconductor structure 100.

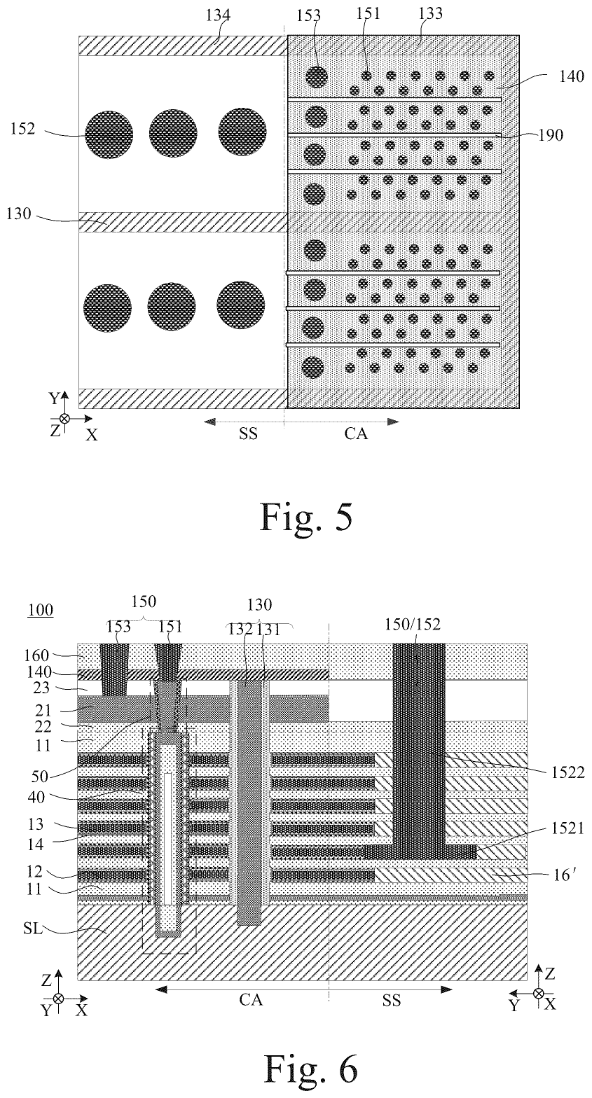

In some implementations, as shown in FIG. 2, the semiconductor structure 100 may include a storage region CA and a connection region SS. Referring to FIGS. 2 and 5, the gate line isolation structure 130 may include a first part 133 in the storage region and a second part 134 in the connection region SS. The first dielectric layer 140 may be located in the storage region CA, may contact the first part 133, and may cover a surface of the first part 133 away from the semiconductor layer SL.

In some implementations, referring to FIGS. 2 and 5, the semiconductor structure 100 may further include a second conductive post 152 located in the connection region SS. The second conductive post 152 penetrates through the second dielectric layer 160, the second stack structure 120 and a part of the first stack structure 110, and one second conductive post 152 may be connected with one gate line layer 12. The second conductive post 152 may be configured to lead out the gate line layer 12 so as to facilitate transferring electrical signals to the gate line layer 12.

As shown in FIG. 5, the semiconductor structure 100 may further include select gate line isolation structures 190. At least one select gate line isolation structure 190 may be included between adjacent two gate line isolation structures 130 in the second direction Y. The select gate line isolation structures 190 may penetrate through the second stack structure 120 to separate the select gate line layer 21 into a plurality of sub-select gate lines. The material for the select gate line isolation structures 190 may include insulating material such as silicon oxides. The select gate line isolation structures 190 may improve the control precision of the semiconductor structure 100. This may facilitate an accurate controlling of the memory cell strings. The select gate line isolation structure 190 may extend as a straight line or a curve in the first direction X, which is not limited in implementations of the present disclosure. The extension direction of the select gate line isolation structures 190 in FIG. 5 is only illustrative rather than limiting, and the extension direction of the select gate line isolation structures 190 may be selected flexibly according to use-case scenarios.

In some implementations, as shown in FIG. 2, the semiconductor structure 100 may include a step structure 170 in which the first stack structure 110 in the connection region SS form a plurality of steps. One step includes one first insulating layer 11 and one gate line layer 12. In one step, the gate line layer 12 may be over the first insulating layer 11 (as shown in FIG. 2), or the first insulating layer 11 is over the gate line layer 12 (not shown).

The first stack structure 110 may further include a covering layer 15 on the step structure 170 that covers the step structure 170. By way of example and not limitation, the material for the covering layer 15 may be an insulating material. For example, the material for the covering layer 15 may be the same as the first insulating layer 11. At this time, the second conductive post 152 may penetrate through a part of the first stack structure 110. It may be possible that the second conductive post 152 penetrates through the covering layer 15 and is connected with a gate line layer 12 of a step.

In some other implementations, referring to FIG. 6, the second conductive post 152 may adopt a self-align contact (SCT) architecture. The SCT architecture does not constitute a staircase structure, but is embedded in the second conductive post 152 in the connection region SS and leads out the gate line layer 12 via the second conductive post 152. Here, the first stack structure 110 may further include a plurality of sacrificial patterns 16′ located in the connection region SS. Each sacrificial pattern 16′ may be disposed in the same layer as one gate line layer 12 and contacts the gate line layer 12 of the same layer.

As shown in FIG. 6, the second conductive post 152 may include a first sub-section 1521 and a second sub-section 1522. The first sub-section 1521 may be disposed in the same layer as one gate line layer 12 and one sacrificial pattern 16′ and may be connected with the gate line layer 12 of the same layer. The second sub-section 1522 may penetrate through the sacrificial pattern 16′ over the first sub-section 1521.

As shown in FIGS. 2 and 6, since the first dielectric layer 140 does not cover the connection region SS, there is a spacing between the second conductive post 152 and the first dielectric layer 140.

In some implementations, as shown in FIG. 6, the semiconductor structure 100 may further include a third conductive post 153. The third conductive post 153 may penetrate through the second dielectric layer 160, the first dielectric layer 140, and the third dielectric layer 23. This third conductive post 153 may be connected with the select gate line layer 21. The third conductive post 153 may be configured to lead out the select gate line layer 21 so as to facilitate transferring electrical signals to the select gate line layer 21.

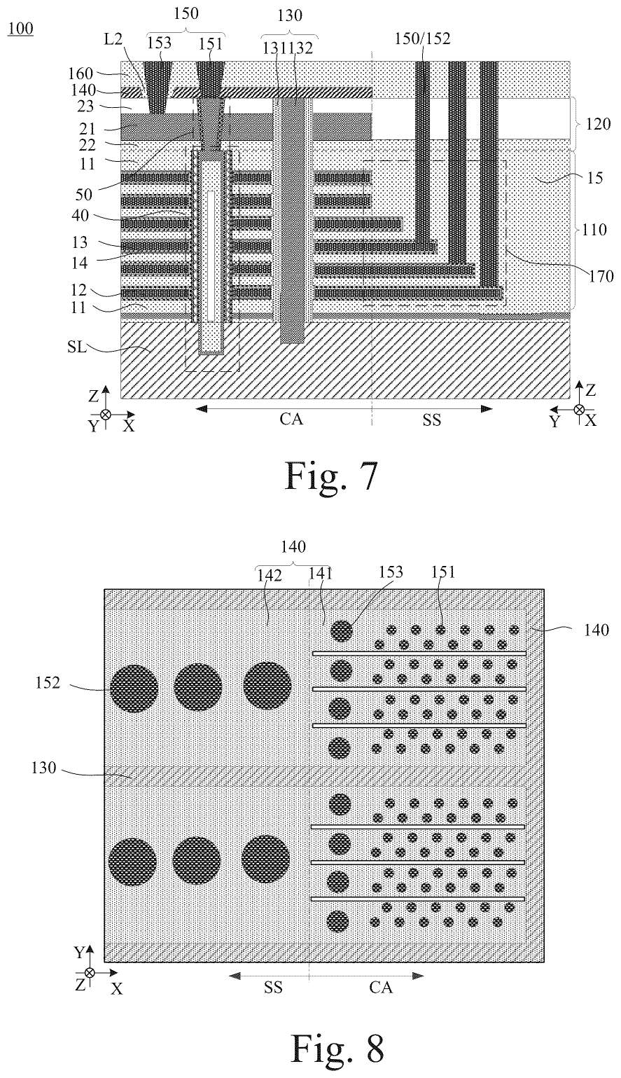

The third conductive post 153 may be located in the storage region CA, and the first dielectric layer 140 may surround the third conductive post 153. By way of example and not limitation, in the fabrication process of the semiconductor structure 100, prior to forming the second dielectric layer 160, it may be possible to pattern the first dielectric layer 140 first to provide an avoiding hole in the first dielectric layer 140. Then, the second dielectric layer 160 and the third conductive post 153 may be formed such that the third conductive post 153 is formed to directly contact the sidewall of the avoiding hole or there is a certain spacing between the third conductive post 153 and the avoiding hole. Thus, it may be possible to reduce the fabrication difficulty of the third conductive post 153. For example, it may be possible to reduce the shaping difficulty of contact holes of the third conductive post 153. Based on this, as shown in FIG. 6, the first dielectric layer 140 may contact the third conductive post 153. Alternatively, as shown in FIG. 7, there may be a second spacing L2 between the first dielectric layer 140 and the third conductive post 153, and a part of the second dielectric layer 160 may be filled in the second spacing L2.

In some other implementations, as shown in FIG. 8, the first dielectric layer 140 is located in the storage region CA and the connection region SS, and the first dielectric layer 140 covers the surface of the gate line isolation structure 130 away from the semiconductor layer SL. That is, the first dielectric layer 140 includes a third part 141 in the storage region CA and a fourth part 142 in the connection region SS, and the first dielectric layer 140 covers the entire upper surface of the gate line isolation structure 130.

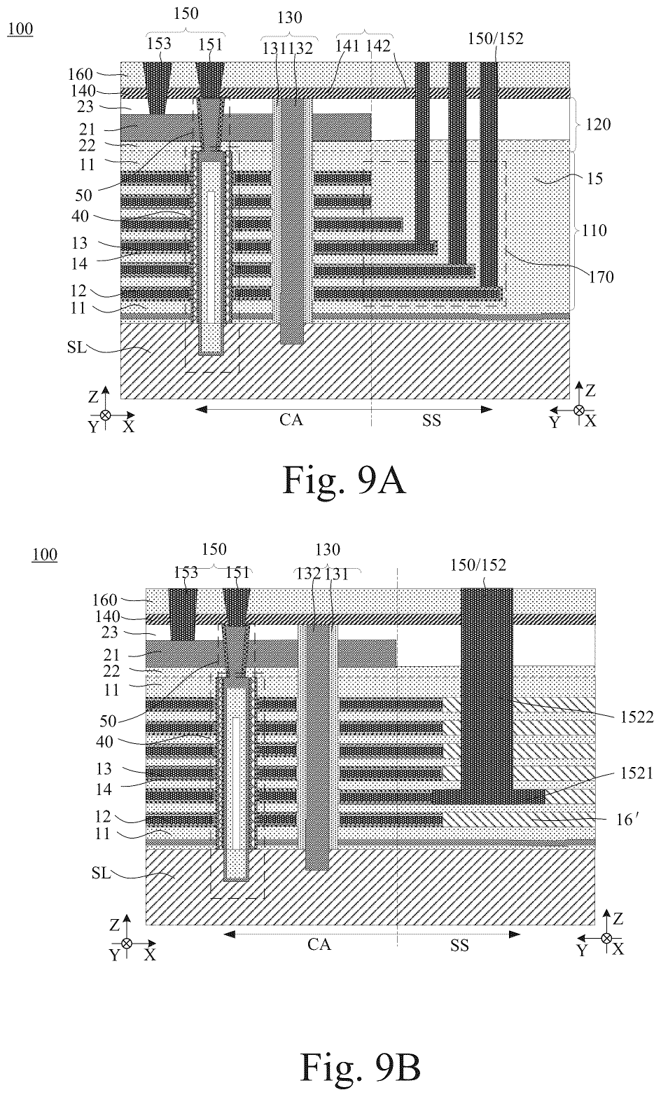

As shown in FIGS. 9A and 9B, in case that the first dielectric layer 140 is located in the storage region CA and the connection region SS, the second conductive post 152 in the connection region SS may penetrate through the second dielectric layer 160, the first dielectric layer 140, the second stack structure 120, and a part of the first stack structure 110. The second conductive post 152 may be connected with the gate line layer 12.

The second conductive post 152 has functions as described above, which will not be repeated hereinbelow. The first dielectric layer 140 may further surround and contact the second conductive post 152. Thus, prior to forming the second dielectric layer 160, it may not be necessary to pattern the first dielectric layer 140, which facilitates simplifying the fabrication process of semiconductor structure 100.

As shown in FIGS. 9A and 9B, in case that the first dielectric layer 140 is located in the storage region CA and the connection region SS, the third conductive post 153 may penetrate through the second dielectric layer 160 and the first dielectric layer 140, and may be connected with the select gate line layer 21. The third conductive post 153 has functions as described above, which will not be described herein. The first dielectric layer 140 may surround the third conductive post 153 and contact the third conductive post 153. Similar to the second conductive post 152, prior to forming the second dielectric layer 160, it may be not necessary to pattern the first dielectric layer 140, which facilitates simplifying the fabrication process of semiconductor structure 100.

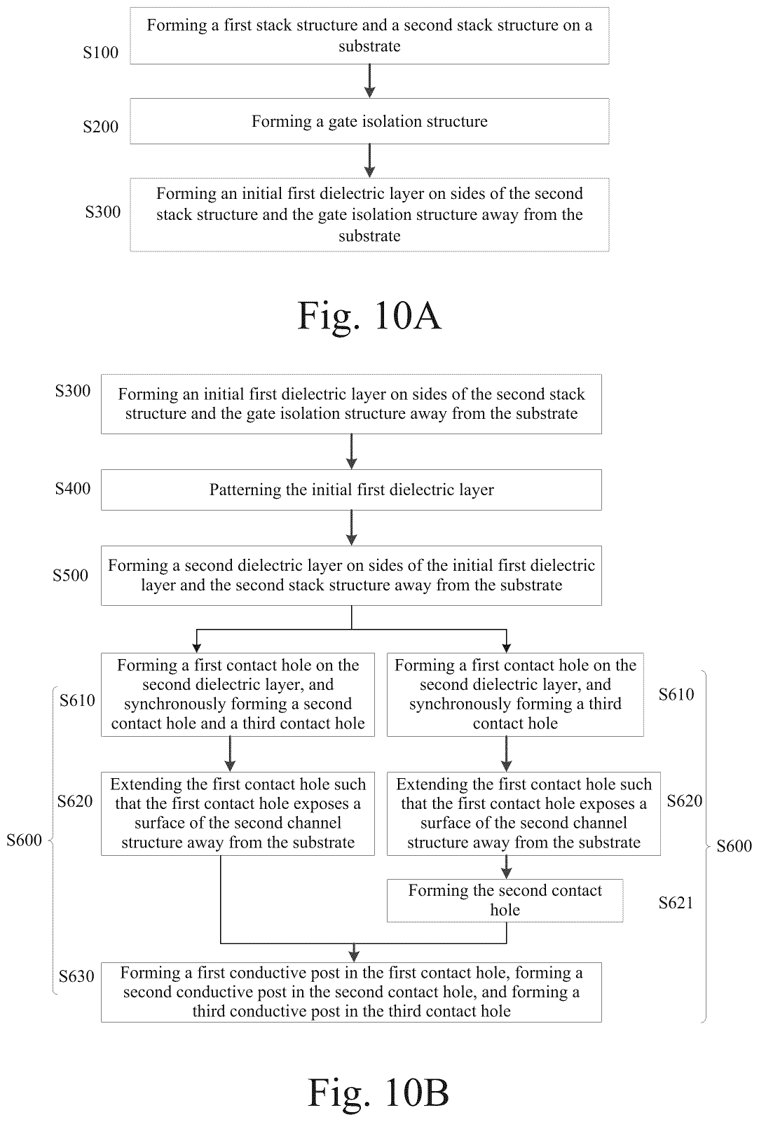

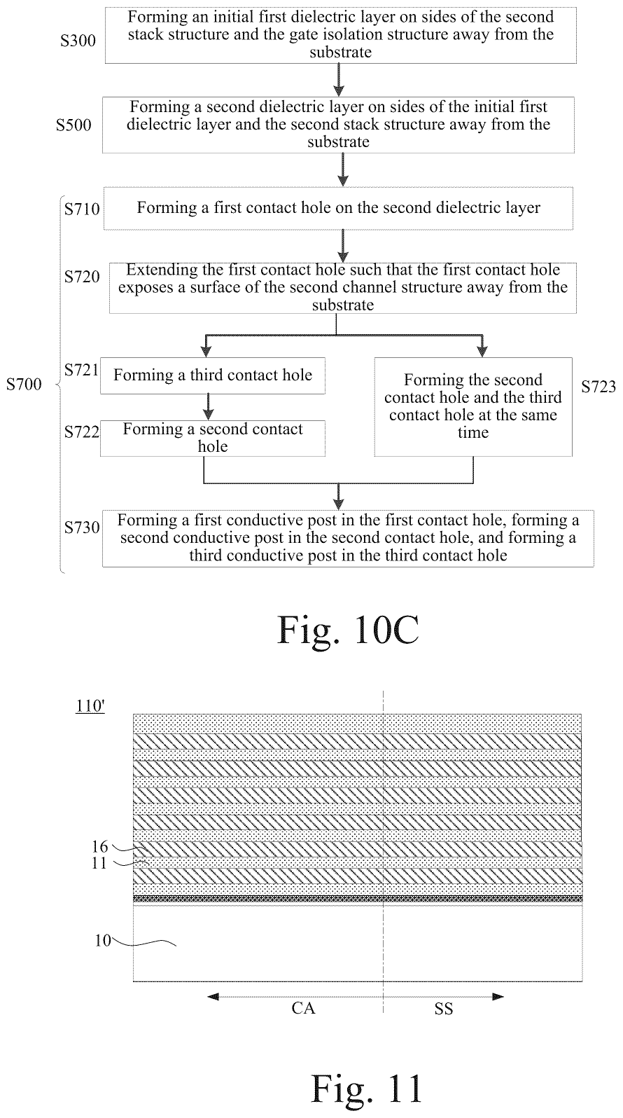

Some implementations of the present disclosure further provide a fabrication method of a semiconductor structure for fabricating the semiconductor structure 100 in any one of the above-described implementations. Referring to FIG. 10A, the fabrication method may include operations S100-S300.

Referring to FIG. 10A, at operation S100, the method may include forming a first stack structure 110 and a second stack structure 120 on a substrate 10. As described above, the first stack structure 110 includes a plurality of first insulating layers 11 and a plurality of gate line layers 12 disposed alternatively, and the second stack structure 120 includes at least one select gate line layer 21. In some implementations, the above-described operation S100 of forming a first stack structure 110 and a second stack structure 120 on a substrate 10 may include S110-S170.

For example, referring to FIG. 11, at operation S110, the method may include forming a first initial stack structure 110′ on a substrate 10.

The first initial stack structure 110′ includes a plurality of first insulating layers 11 and a plurality of first sacrificial layers 16 disposed alternatively. The materials for the first insulating layers 11 and the first sacrificial layers 16 may be different such that the first insulating layers 11 and the first sacrificial layers 16 have different etch selection ratios under the same etching conditions to facilitate removing the first sacrificial layers 16 selectively in subsequent fabrication process and retaining the first insulating layers 11. By way of example and not limitation, in case that the material for the first insulating layers 11 includes silicon oxide, the material for the first sacrificial layers 16 may be silicon nitride.

Forming the first initial stack structure 110′ on the substrate 10 may include, for example, forming one first insulating layer 11 on the surface of the substrate 10. The forming the first initial stack structure 110′ may include forming one first sacrificial layer 16 on the surface of the first insulating layer 11. The forming the first initial stack structure 110′ may include forming a first insulating layer 11 and a first sacrificial layer 16 in a repeated fashion. The forming the first initial stack structure 110′ may include forming one first insulating layer 11 to fabricate the first initial stack structure 110′ having a plurality of first insulating layers 11 and a plurality of first sacrificial layers 16 stacked alternatively.

By way of example and not limitation, the first insulating layers 11 and the first sacrificial layers 16 may be formed with a film deposition process, e.g., such as chemical vapor deposition (CVD), physical vapor deposition (PVD), atomic layer deposition (ALD), or any combination thereof.

For example, silicon oxide material layers (first insulating layers 11) and silicon nitride material layers (first sacrificial layers 16) are deposited alternatively on the substrate 10 with CVD process to form the first insulating layers 11 and the first sacrificial layers 16 stacked alternatively, thereby obtaining the first initial stack structure 110′.

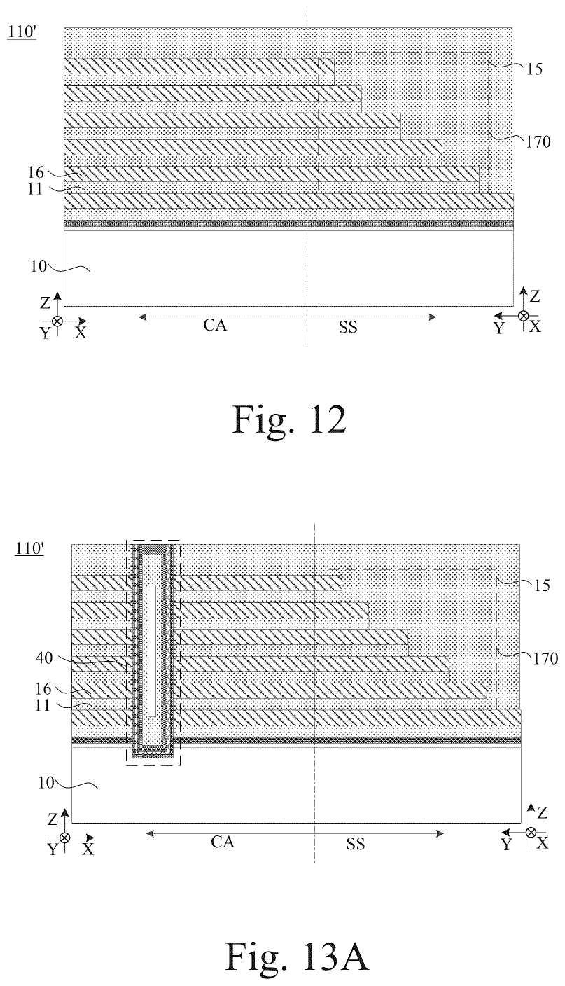

When the semiconductor structure 100 adopts the step structure, after forming the first initial stack structure 110′ on a substrate 10 in S110, as shown in FIG. 12, the fabrication method of the semiconductor structure further includes forming a step structure 170 and a covering layer 15 in the connection region.

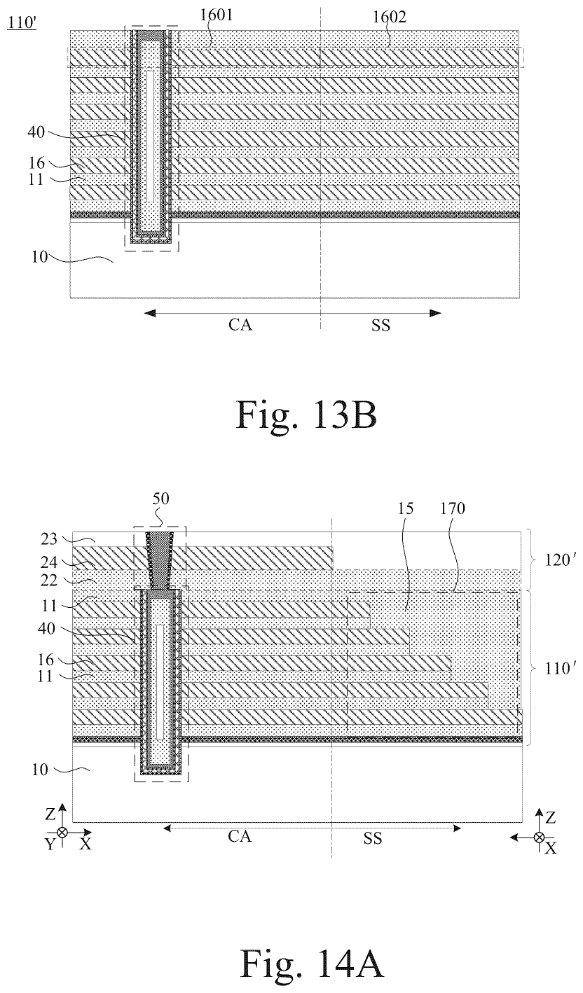

Referring again to FIGS. 13A and 13B, at operation S120, the method may include forming a plurality of first channel structures 40 penetrating through the first initial stack structure 110′.

In some implementations, in case that the first initial stack structure 110′ includes the step structure 170, the structure shown in FIG. 13A may be formed; and in case that the semiconductor structure adopts the SCT architecture, the structure shown in FIG. 13B may be formed. By way of example and not limitation, the fabrication process of the first stack structure and the second stack structure is described below with respect to an example in which the first initial stack structure 110′ includes the step structure 170.

For instance, the above-described process of forming a plurality of first channel structures 40 may include operations S121 and S122. At operation S121, the method may include forming a plurality of first channel holes penetrating through the first initial stack structure 110′ with dry or wet etch. At operation S122, the method may include forming a barrier layer 411, a charge trapping layer 412, and a tunneling layer 413, as well as a first channel layer 42 in the first channel holes with any one or more processes, e.g., such as CVD, PVD, and ALD.

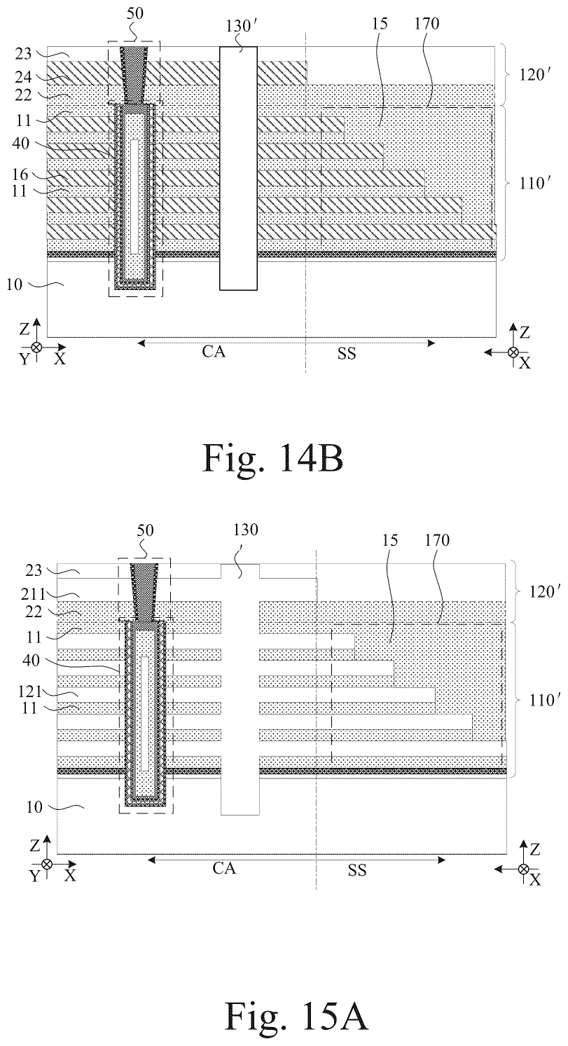

Referring to FIG. 14A, at operation S130, the method may include forming a second initial stack structure 120′ on sides of the first initial stack structure 110′ and the plurality of first channel structures 40 away from the substrate 10.

The second initial stack structure 120′ may include at least one second sacrificial layer 24. The second sacrificial layer 24 and the first sacrificial layer 16 may have the same selection ratios under the same etching conditions. By way of example and not limitation, the material for the second sacrificial layer 24 and the material for the first sacrificial layer 16 may be the same such that the second sacrificial layer 24 is removed simultaneously in the process of subsequently removing the first sacrificial layer 16. For example, the materials for the first sacrificial layer 16 and the second sacrificial layer 24 may be silicon nitride.

By way of example and not limitation, it may be possible to form the at least one second sacrificial layer 24 with any one process of such as CVD, PVD, and ALD. By way of example and not limitation, the second sacrificial layer 24 may be located in the storage region CA.

In some implementations, the second initial stack structure 120′ may further include a second insulating layer 22 and a third dielectric layer 23; and the process of forming the second initial stack structure 120′ may include forming successively the second insulating layer 22, the second sacrificial layer 24, and the third dielectric layer 23 with any one process of CVD, PVD, and ALD.

Referring again to FIG. 14A, at operation S140, the method may include forming a plurality of second channel structures 50 penetrating the second initial stack structure 120′.

The above-described process of forming the second channel structure 50 may for example include operations S141 and S142.

For example, at operation S141, the method may include forming a second channel hole penetrating through the second initial stack structure 120′ with dry or wet etch. The second channel hole exposes at least part of the first channel structure 40. For example, the second channel hole exposes at least part of the upper end surface of the first channel layer 42 of the first channel structure 40.

At operation S142, the method may include forming a gate dielectric layer 51 and a second channel layer 52 successively in the second channel hole with any one process of such as CVD, PVD, and ALD. The second channel layer 52 may be in contact with and connected with the first channel layer 42 such that each second channel structure 50 is connected with one first channel structure 40.

Referring to FIG. 14B, at operation S150, the method may include forming a gate line isolation trench 130′. The gate line isolation trench 130′ penetrates through the first initial stack structure 110′ and the second initial stack structure 120′ in a direction perpendicular to the substrate 10 (third direction Z).

By way of example and not limitation, the gate line isolation trench 130′ may extend into the substrate 10 by a certain depth from the upper surface of the second initial stack structure 120′ (surface away from the substrate 10) in a direction perpendicular to the substrate 10 (third direction Z). By way of example and not limitation, the gate line isolation trench 130′ may be formed with dry/wet etch process.

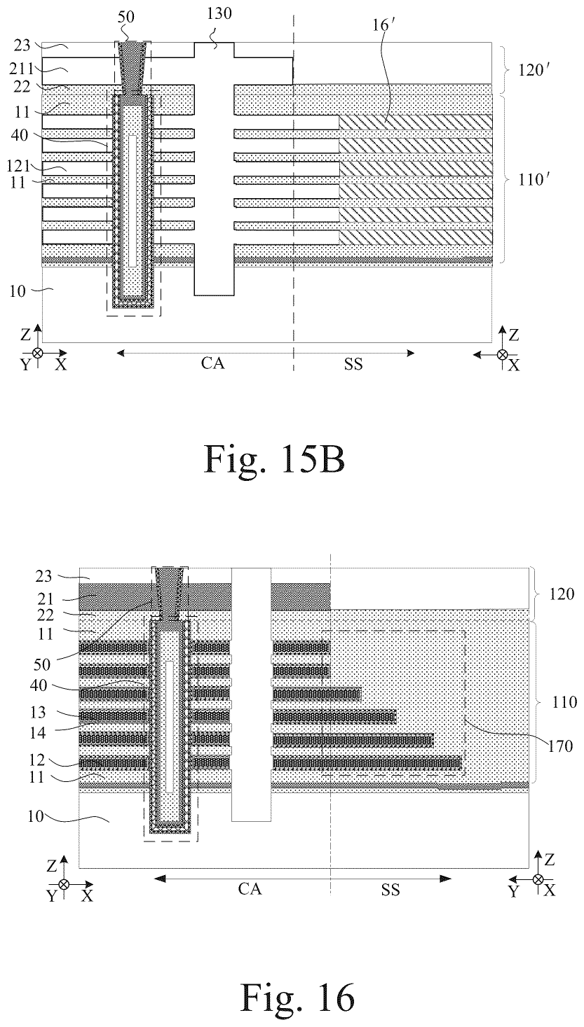

Referring to FIGS. 15A and 15B, at operation S160, the method may include removing at least partial first sacrificial layer 16 via the gate line isolation trench 130′ to form a gate line layer cavity 121 and removing the second sacrificial layer 24 to form a select gate line layers cavity 211.

By way of example and not limitation, as shown in FIG. 15A, in case that the semiconductor structure 100 includes a step structure 170, it may be possible to remove the entirety of each first sacrificial layer 16.

Alternatively, by way of example and not limitation, as shown in FIGS. 13B and 15B, in case that the semiconductor structure 100 adopts the SCT architecture, the first sacrificial layer 16 may include a third sub-section 1601 in the storage region CA and a fourth sub-section 1602 in the connection region SS. It may be possible to remove the entirety of the third sub-section 1601 of each first sacrificial layer 16, to remove a part of the fourth sub-section 1602 of each first sacrificial layer 16 close to the gate line isolation trench 130′, and to retain a part of the first sacrificial layer 16 in the connection region SS to form the sacrificial pattern 16′.

By way of example and not limitation, it is possible to remove at least part of the first sacrificial layer 16 and second sacrificial layer 24 with dry/wet etching.

Referring to FIG. 16, at operation S170, the method may include forming a gate line layer 12 in the gate line layer cavity and forming a first stack structure 110; and forming a select gate line layer 21 in the select gate line layer cavity to form the second stack structure 120. Still referring to FIG. 16, operation S170 is illustrated with respect to an example in which the first stack structure 110 includes a step structure 170.

The material for the gate line layers 12 and the select gate line layer 21 include conductive materials, e.g., such as one or more of tungsten, cobalt, copper, aluminum, doped crystalline silicon, or silicide.

By way of example and not limitation, it may be possible to fabricate the gate layer, the gate line layers 12 and the select gate line layer 21 with any one process of such as CVD, PVD, and ALD.

In some implementations, prior to S170, the fabrication method may further include S170′.

For instance, at operation S170′, the method may include forming successively a fourth dielectric layer 14 and a metal compound layer 13 in the gate line layer cavity and the select gate line layer cavity. The fourth dielectric layer 14 covers the metal compound layer 13 to reduce the risk of charges in the first channel structure 40 flowing to the gate line layers 12. The metal compound layer 13 covers the gate line layer 12 and the select gate line layer 21, and the metal compound layer 13 is configured to improve the adhesion between the gate line layers 12, the select gate line layer 21, and the fourth dielectric layer 14. By way of example and not limitation, it may be possible to fabricate the fourth dielectric layer 14 and the metal compound layer 13 with any one process of such as CVD, PVD, and ALD.

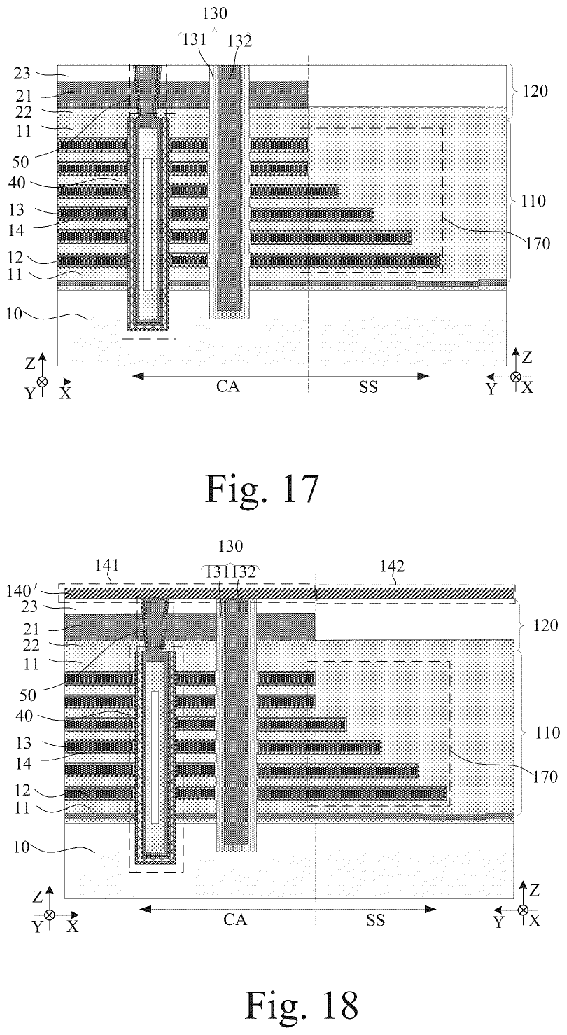

Referring to FIG. 17, at operation S200, the method may include forming a gate line isolation structure 130. In FIG. 17, operation S200 is illustrated with respect to an example in which the first stack structure 110 includes a step structure 170.

By way of example and not limitation, the gate line isolation structure 130 may include a third insulating layer 131 and an intermediate filling layer 132. The third insulating layer 131 may be configured to prevent short circuit between different gate line layers 12 and oxidation of gate line layers 12. The material for the third insulating layer 131 includes insulating material, e.g., such as silicon oxide. The intermediate filling layer 132 may be configured to provide mechanical support, and the material for the intermediate filling layer 132 may be conductive material or insulating material. For example, the material for the intermediate filling layer 132 may include poly-crystalline silicon, silicon oxide, or silicon oxynitride, just to name a few. In some other implementations, the gate line isolation structure 130 may include only one insulating layer. The material for the insulating layer may be silicon oxide.

By way of example and not limitation, the third insulating layer 131 and the intermediate filling layer 132 may be formed successively with any one of such as CVD, PVD, and ALD. The processes for forming the third insulating layer 131 and the intermediate filling layer 132 may be the same or different.

Referring to FIG. 18, at operation S300, the method may include forming an initial first dielectric layer 140′ on sides of the second stack structure 120 and the gate line isolation structure 130 away from the substrate 10. In FIG. 18, operation S300 is illustrated with respect to an example in which the first stack structure 110 includes a step structure 170.

The initial first dielectric layer 140′ covers surfaces of the second stack structure 120 and the gate line isolation structure 130 away from the substrate 10. That is, the initial first dielectric layer 140′ is a continuous structure of an entire layer and covers the upper surfaces of the second stack structure 120 and the gate line isolation structure 130. The material for the initial first dielectric layer 140′ may include silicon nitride.

By way of example and not limitation, it may be possible to fabricate the initial first dielectric layer 140′ with any one process of such as CVD, PVD, and ALD. The initial first dielectric layer 140′ may include a third part 141 in the storage region CA and a fourth part 142 in the connection region SS.

Referring to FIG. 10B, after forming the initial first dielectric layer 140′ in step S300, the fabrication method of semiconductor structure 100 may further include operation S400.

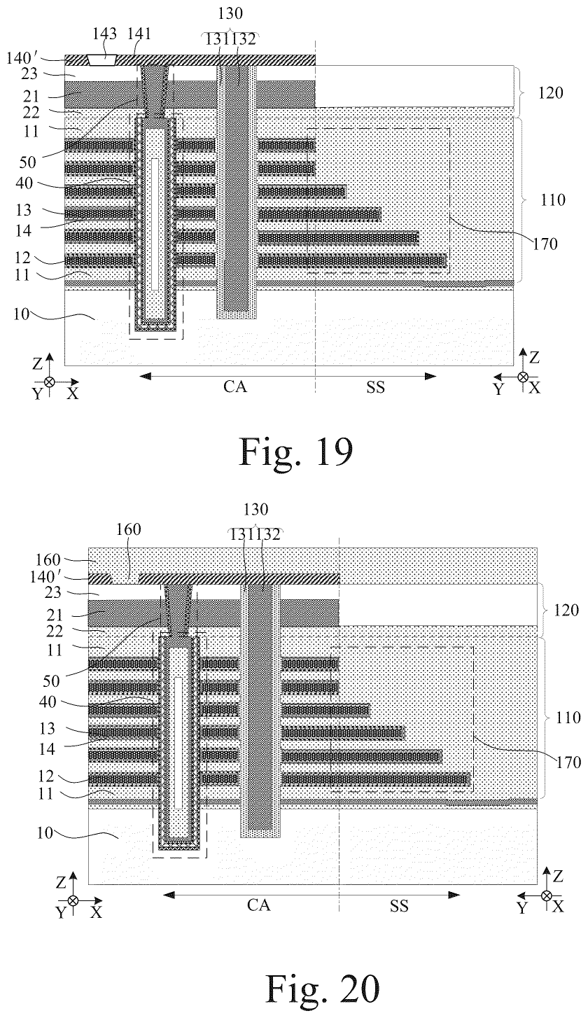

For example, referring to FIG. 19, at operation S400, the method may include patterning the initial first dielectric layer 140′. The fourth part 142 in the initial first dielectric layer 140′ is removed. A first avoiding hole 143 is formed in the third part 141 of the initial first dielectric layer 140′ such that there is a spacing between the first avoiding hole 143 and the gate line isolation structure 130. In FIG. 19, operation S400 is illustrated with respect to an example in which the first stack structure 110 includes a step structure 170.

By way of example and not limitation, the orthogonal projection of the first avoiding hole 143 on the substrate 10 falls within the range of the orthogonal projection of the select gate line layer 21 on the substrate 10. The initial first dielectric layer 140′ may be patterned with dry/wet etching.

After patterning the initial first dielectric layer 140′ in step S400, the fabrication method of semiconductor structure 100 may further include operations S500 and S600.

For example, referring to FIG. 20, at operation S500, the method may include forming a second dielectric layer 160 on sides of the initial first dielectric layer 140′ and the second stack structure 120 away from the substrate 10. In FIG. 20, operation S620 is illustrated with respect to an example in which the first stack structure 110 includes a step structure 170.

By way of example and not limitation, the second layer 160 and the first dielectric layer 140 have different selection ratios under the same etching conditions, and have different materials. In case that the material for the first dielectric layer 140 is silicon nitride, the material for the second dielectric layer 160 may be silicon oxide. By way of example and not limitation, it is possible to form the second dielectric layer 160 with any one process of such as CVD, PVD, and ALD.

In some implementations, after forming the second dielectric layer 160, it is also possible to planarize the upper surface of the second dielectric layer 160 with chemical mechanical polishing (CMP) process.

Referring again to FIG. 10B, at operation S600, the method may include forming the first conductive post 151. The first conductive post 151 penetrates through the second dielectric layer 160 and the initial first dielectric layer 140′ and is connected with the second channel structure 50.

In some implementations, operation S600 (e.g., forming the first conductive post 151) may include operations S610-S630.

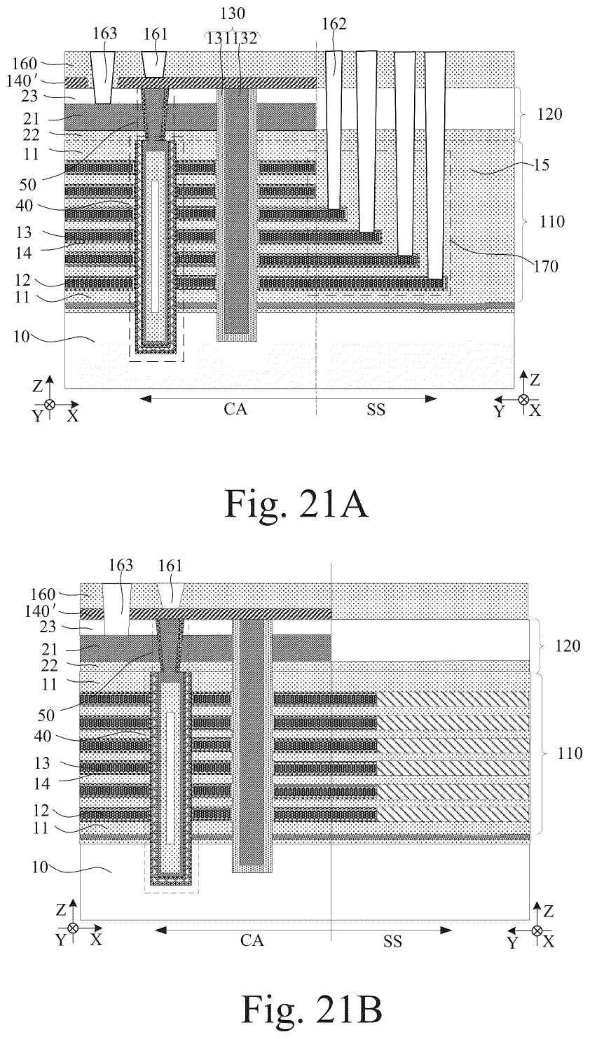

Referring to FIG. 21A, at operation S610, the method may include forming a first contact hole 161 on the second dielectric layer 160. In FIG. 21A, S610 is illustrated with respect to an example in which the first stack structure 110 includes a step structure 170.

The first contact hole 161 penetrates through the second dielectric layer 160 and stops at the initial first dielectric layer 140′.

By way of example and not limitation, the first contact hole 161 may be formed by dry/wet etch process.

In some implementations, in case that the first stack structure 110 includes the step structure 170, referring to FIG. 21A, a second contact hole 162 and a third contact hole 163 are formed at the same time as forming the first contact hole 161 in operation S610. This may simplify the fabrication process of the semiconductor structure 100 and may reduce the fabrication cost of the semiconductor structure 100.

In some implementations, the second contact hole 162 may be located in the connection region SS. The second contact hole 162 may penetrate through the second dielectric layer 160, the second stack structure 120, and a part of the first stack structure 110 (the covering layer 15 of the first stack structure 110). The second contact hole 162 may expose one gate line layer 12. The third contact hole 163 may be located in the storage region. The third contact hole 163 may penetrate through the second dielectric layer 160, may penetrate through the first avoiding hole 143, and may expose one select gate line layer 21. The forming processes for the second contact hole 162 and the third contact hole 163 may be the same as the first contact hole 161, which are not described any more herein.

In some implementations, referring to FIG. 21B, in case that the first stack structure 110 has no step structure 170 and the semiconductor structure adopts SCT architecture, the third contact hole 163 may be formed synchronously at the same time as forming the first contact hole 161 in S610. The third contact hole 163 may be located in the storage region CA, may penetrate through the second dielectric layer 160, may penetrate through the first avoiding hole 143, and may expose one select gate line layer 21. The forming process for the third contact hole 163 may be the same as the first contact hole 161, which are not described any more herein.

In some implementations, as shown in FIG. 21B, the third contact hole 163 may expose sidewall of the first avoiding hole 143; or as shown in FIG. 21A, the third contact hole 163 and the sidewall of the first avoiding hole 143 have partial material of the second dielectric layer 160.

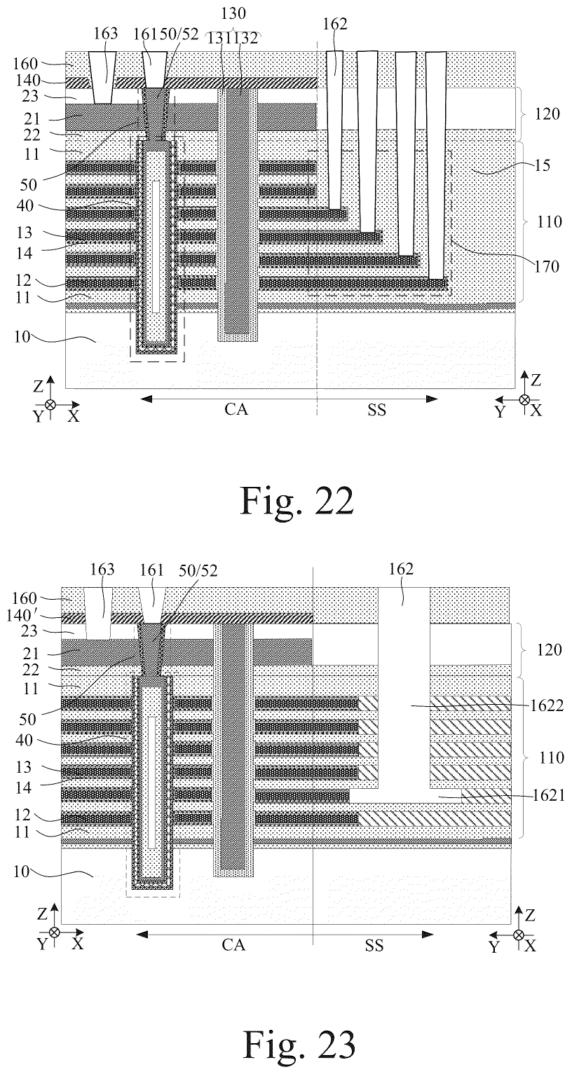

Referring to FIG. 22, at operation S620, the method may include extending the first contact hole 161 such that the first contact hole 161 penetrates through the initial first dielectric layer 140′ and exposes a surface of the second channel structure 50 away from the substrate 10. In FIG. 22, operation S620 is illustrated with respect to an example in which the first stack structure 110 includes a step structure 170.

By way of example and not limitation, the first contact hole 161 may expose the second channel layer 52 of the second channel structure 50. It is possible to etch the part of the initial first dielectric layer 140′ that is exposed by the first contact hole 161 with dry/wet etching process based on the first contact hole 161 to penetrate through the initial first dielectric layer 140′. In some implementations, the initial first dielectric layer 140′, after being penetrated through by the first contact hole 161, may form the first dielectric layer 140.

In case that the first stack structure 110 has no step structure 170 and the semiconductor structure adopts SCT architecture, after extending the first contact hole 161 in operation S620, the method of fabricating the semiconductor structure 100 further includes operation S621.

Referring to FIG. 23, at operation S621, the method may include forming the second contact hole 162.

The second contact hole 162 may include a first sub-hole 1621 and a second sub-hole 1622; and the first sub-hole 1621 is disposed on the same layer as one gate line layer 12 and exposes at least partial sidewall of the gate line layer 12 at the same layer. The second sub-hole 1622 may penetrate through the first stack structure 110 over the first sub-hole 1621 in the third direction and penetrates through the second stack structure 120 and the second dielectric layer 160.

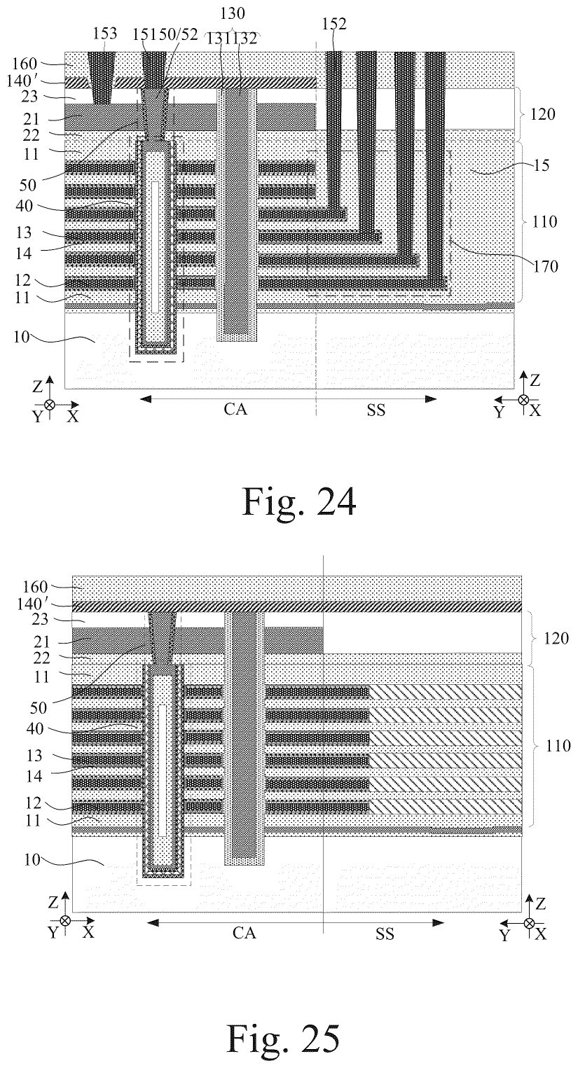

Referring to FIG. 24, at operation S630, the method may include forming the first conductive post 151 in the first contact hole 161. In FIG. 24, operation S630 is illustrated with respect to an example in which the first stack structure 110 includes a step structure 170.

The first conductive post 151 may be connected with the second channel structure 50. The material for the first conductive post 151 may be a conductive material, e.g., such as one or more of tungsten, cobalt, copper, aluminum, metal silicide, etc. By way of example and not limitation, it is possible to form the first conductive post 151 in the first contact hole 161 with any one process of such as CVD, PVD, and ALD.

In some implementations, while forming the first conductive post 151 in the first contact hole 161 in operation S630, a second conductive post 152 may be formed in the second contact hole 162 and a third conductive post 153 may be formed in the third contact hole 163.

In some implementations, the second conductive post 152 may be connected with the gate line layer 12. The third conductive post 153 may be connected with the select gate line layer 21. The materials for the second conductive post 152 and the third conductive post 153 may be the same as the first conductive post 151 and the fabrication processes may be the same, which simplifies the fabrication process of the semiconductor structure and reduces the fabrication cost of the semiconductor structure.

In some other implementations, after forming the initial first dielectric layer 140′ in operation S300, it may be possible to skip or omit operation S400 (e.g., patterning the initial first dielectric layer 140′). Referring to FIG. 10C, now the method of fabricating semiconductor structure 100 may include operations S500 and S700 successively after operation S300.

Referring to FIG. 25, at operation S500, the method may include forming a second dielectric layer 160 on sides of the initial first dielectric layer 140′ and the second stack structure 120 away from the substrate 10. In some implementations, referring to FIG. 25, operation S500 is illustrated with respect to an example in which the semiconductor structure 100 adopts SCT architecture.

The above description may be referred to for the process of forming the second dielectric layer 160 in operation S500, which will not be repeated herein. It is appreciated that since the process of patterning the initial first dielectric layer 140′ of operation S400 is skipped, the upper surface of the initial first dielectric layer 140′ may be considered as planar surface. Thus, the upper surface of the fabricated second dielectric layer 160 may also be considered as a planar surface. Based on this, it is possible to omit the process of planarizing the upper surface of the second dielectric layer 160 with CMP process, which simplifies the fabrication process of the semiconductor structure and reduces the fabrication cost of the semiconductor structure.

Referring again to FIG. 10C, at operation S700, the method may include forming the first conductive post 151.

The first conductive post 151 penetrates through the second dielectric layer 160 and the initial first dielectric layer 140′ and is connected with the second channel structure 50. In some implementations, operation S700 of forming the first conductive post 151 includes operations S710-S730, as shown in FIG. 10C.

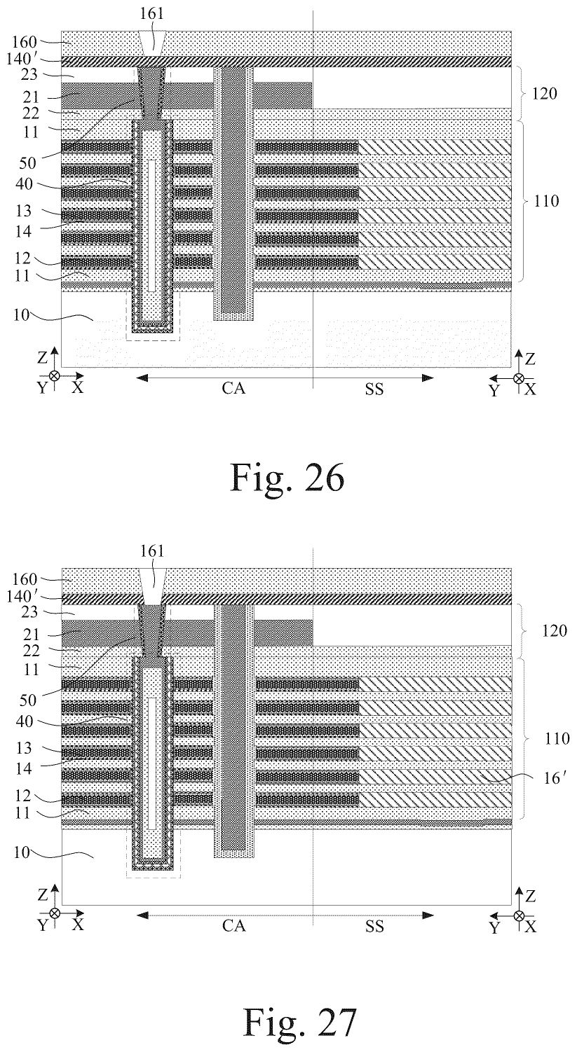

Referring to FIG. 26, at operation S710, the method may include forming the first contact hole 161 on the second dielectric layer 160. The first contact hole 161 may penetrate through the second dielectric layer 160 and may stop at the initial first dielectric layer 140′. In some implementations, referring to FIG. 26, operation S500 is illustrated with respect to an example in which the semiconductor structure 100 adopts SCT architecture.

By way of example and not limitation, the first contact hole 161 may be formed by dry/wet etch process.

Referring to FIG. 27, at operation S720, the method may include extending the first contact hole 161 such that the first contact hole 161 penetrates through the initial first dielectric layer 140′ and exposes a surface of the second channel structure 50 away from the substrate 10. In some implementations, referring to FIG. 27, operation S500 is illustrated with respect to an example in which the semiconductor structure 100 adopts SCT architecture.

By way of example and not limitation, the first contact hole 161 may expose the second channel layer 52 of the second channel structure 50. It is possible to etch the part of the initial first dielectric layer 140′ that is exposed by the first contact hole 161 with dry/wet etching process based on the first contact hole 161 to penetrate through the initial first dielectric layer 140′. In some implementations, the initial first dielectric layer 140′, after being penetrated through by the first contact hole 161, may form the first dielectric layer 140.

In some implementations, after extending the first contact hole 161 in operation S720, the method of fabricating the semiconductor structure may further include operations S721 and S722. Operations S721 and S722 may be adopted whether the first stack structure 110 adopts the step structure or the SCT architecture.

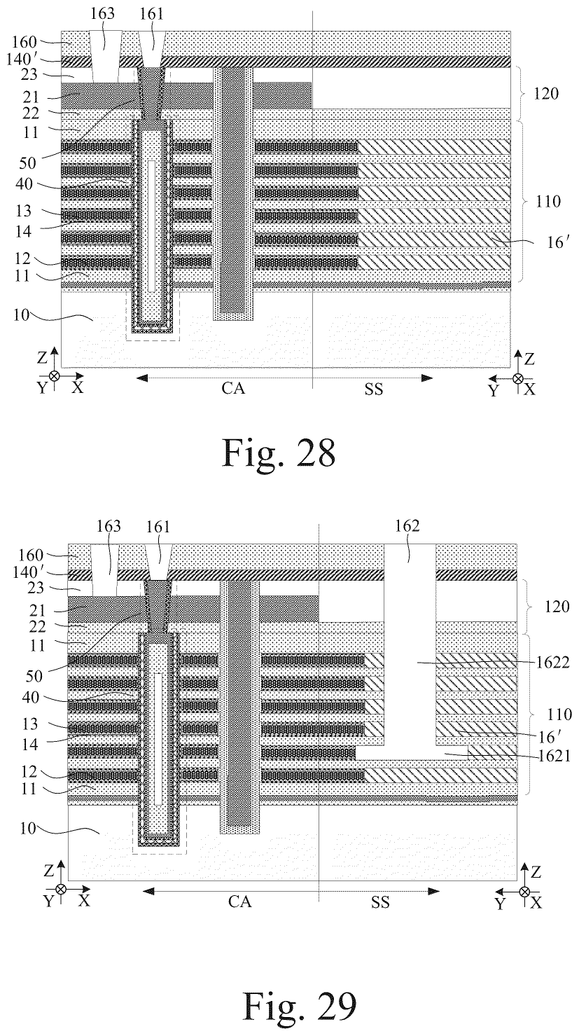

Referring to FIG. 28, at operation S721, the method may include forming the third contact hole 163. In some implementations, referring to FIG. 28, operation S500 is illustrated with respect to an example in which the semiconductor structure 100 adopts SCT architecture.

The third contact hole 163 is located in the storage region, penetrates through the second dielectric layer 160, the first dielectric layer 140, and the third dielectric layer 23, and exposes a select gate line layer 21. By way of example and not limitation, the third contact hole 163 may be formed by dry/wet etch process.

Since the process of patterning the initial first dielectric layer 140′ in operation S400 is omitted, the third contact hole 163 formed during operation S721 further exposes sidewall of the initial first dielectric layer 140.

Referring to FIG. 29, at operation S722, the method may include forming the second contact hole 162. In some implementations, referring to FIG. 29, operation S500 is illustrated with respect to an example in which the semiconductor structure 100 adopts SCT architecture.

The second contact hole 162 is located in the connection region SS and penetrates through the second dielectric layer 160, the initial first dielectric layer 140′, the second stack structure 120, and a part of the first stack structure 110, and exposes one gate line layer 12. By way of example and not limitation, the second contact hole 162 may be formed by dry/wet etch process.

As shown in FIG. 29, after forming the second contact hole 162, the initial first dielectric layer 140′ forms the first dielectric layer 140. The second contact hole 162 further exposes partial sidewall of the first dielectric layer 140.

In some implementations, the order of operation S721 (e.g., forming the third contact hole 163) and operation S722 (e.g., forming the second contact hole 162) may be interchangeable.

In some other implementations, in case that the first stack structure 110 includes the step structure 170, after extending the first contact hole 161 during operation S720, the method of fabricating the semiconductor structure may further include operation S723.

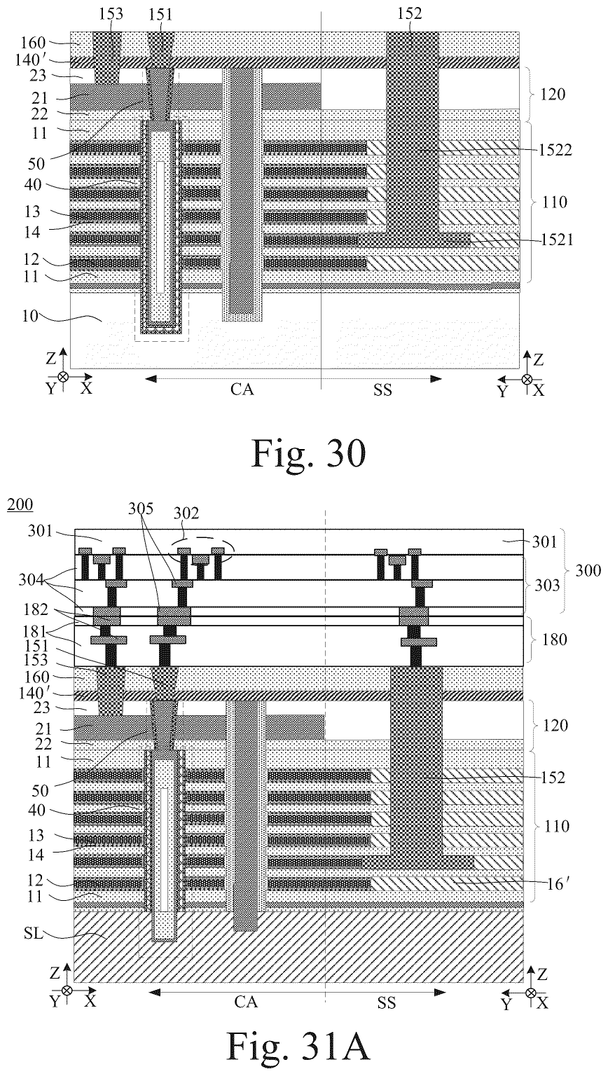

Referring to FIG. 30, at operation S723, the method may include forming the second contact hole 162 and the third contact hole 163 at the same time. In FIG. 30, operation S500 is illustrated with respect to an example in which the semiconductor structure 100 adopts SCT architecture.

The second contact hole 162 is located in the connection region SS. The second contact hole 162 penetrates through the second dielectric layer 160, the initial first dielectric layer 140′, the second stack structure 120, and a part of the first stack structure 110. The second contact hole 162 exposes one gate line layer 12. The third contact hole 163 is located in the storage region. The third contact hole 163 may penetrate through the second dielectric layer 160, the first dielectric layer 140, and the third dielectric layer 23. The third contact hole 163 may expose a select gate line layer 21. By way of example and not limitation, the second contact hole 162 and the third contact hole 163 may be formed simultaneously by dry/wet etch process. Forming the second contact hole 162 and the third contact hole 163 simultaneously may simplify the fabrication process of the semiconductor structure and may reduce the fabrication cost of the semiconductor structure.

Referring to FIG. 30, at operation S730, the method may include forming the first conductive post 151 in the first contact hole 161 that is connected with the second channel structure 50.

The first conductive post 151 is connected with the second channel structure 50. The material for the first conductive post 151 may be a conductive material such as one of tungsten, cobalt, copper, aluminum and metal silicide or a combination thereof. By way of example and not limitation, it is possible to form the first conductive post 151 in the first contact hole 161 with any one process of CVD, PVD, and ALD.

In some implementations, as shown in FIG. 30, while forming the first conductive post 151 in the first contact hole 161 in S730, a second conductive post 152 may further be formed in the second contact hole 162 and a third conductive post 153 may be formed in the third contact hole 163.

In some implementations, the second conductive post 152 is connected with the gate line layer 12. The third conductive post 153 is connected with the select gate line layer 21. The materials for the second conductive post 152 and the third conductive post 153 may be the same as the first conductive post 151 and the fabrication processes may be the same, which facilitates simplifying the fabrication process of the semiconductor structure and reducing the fabrication cost of the semiconductor structure.

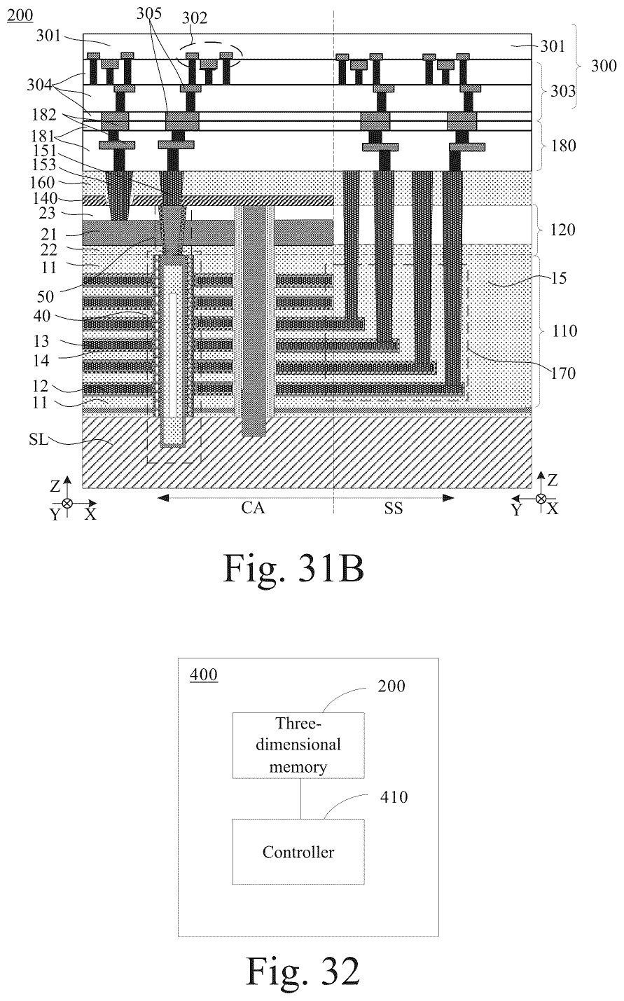

Referring to FIGS. 31A and 31B, some implementations of the present disclosure further provide a three-dimensional memory 200. The three-dimensional memory 200 may include any of the above-described semiconductor structures 100 and a peripheral device 300. The semiconductor structure 100 may be connected with the peripheral device 300 to implement function support of the peripheral device 300 for the semiconductor structure 100, e.g., such as reading, writing, and erasing data in the memory cells.

The semiconductor structure 100 may further include an array interconnection layer 180 disposed on a side of the second dielectric layer 160 away from the semiconductor layer SL. The array interconnection layer 180 may include at least one first interlayer insulating layer 181 and at least one first interconnection conductor layer 182. The first interconnection conductor layer 182 may include a plurality of connection lines such as bit lines and word line connection lines coupled with word lines (not shown).

The material for the above first interlayer insulation layer 181 may include an insulating material that includes one or more of silicon oxide, silicon nitride, silicon oxynitride, doped silicon dioxide, organic silicate glass, dielectric metallic oxide (such as aluminum oxide, and hafnium dioxide), and silicate thereof, and organic insulating materials. The material for the first interconnection conductor layer 182 may be a conductive material such as one of tungsten, cobalt, copper, aluminum and metal silicide or a combination thereof.

Referring again to FIGS. 31A and 31B, the peripheral device 300 may be disposed over the semiconductor structure 100 (such as on a side of the array interconnection layer 180 away from the semiconductor layer SL), and may include a peripheral circuit. The peripheral circuit may be configured to control and sense the semiconductor structure 100. The peripheral circuit may be any suitable digital, analog and/or hybrid signal control and sense circuit for supporting the operation (or work) of the semiconductor structure 100, including, but not limited to, a page buffer, a decoder (such as a row decoder and a column decoder), a sense amplifier, a driver (such as a gate line driver), a charge pump, a current or voltage reference or any active or inactive components of a circuit such as a transistor, a diode, a resistor or a capacitor. The peripheral circuit may further include any other circuits compatible with advanced logic processes, including a logic circuit such as a processor and a programmable logic device (PLD) or a memory circuit such as a static random access three-dimensional memory (SRAM).

In some implementations, as shown in FIGS. 31A and 31B, the peripheral device 300 may include a substrate 301, a peripheral circuit disposed on the substrate 301, and a peripheral interconnection layer 303 disposed on the substrate 301. The peripheral circuit may include a transistor 302.

Herein, the material for the substrate 301 may be single crystalline silicon or other suitable materials such as silicon germanium, germanium or silicon-on-insulator film.

The peripheral interconnection layer 303 may be coupled with a transistor 302 for electric signal transmission between the transistor 302 and the peripheral interconnection layer 303. The peripheral interconnection layer 303 may include one or more second interlayer insulating layers 304 and may further include one or more second interconnection conductor layers 305. Different second interconnection conductor layers 305 may be coupled via contacts.

By way of example and not limitation, the material for the above-described second interlayer insulating layer 304 is an insulating material, e.g., such as one or more of silicon oxide, silicon nitride, and high dielectric constant insulating material. The materials for the second interconnection conductor layer 305 and contacts may be a conductive material such as one of tungsten, cobalt, copper, aluminum and metal silicide or a combination thereof.

The above-described peripheral interconnection layer 303 of the peripheral device 300 may be coupled with the array interconnection layer 180 of the semiconductor structure 100 such that the semiconductor structure 100 is coupled with the peripheral device 300, which in turn couples the peripheral circuit in the peripheral device 300 with the memory cell strings in the semiconductor structure 100 for electrical signal transmission between the peripheral circuit and the memory cell strings.

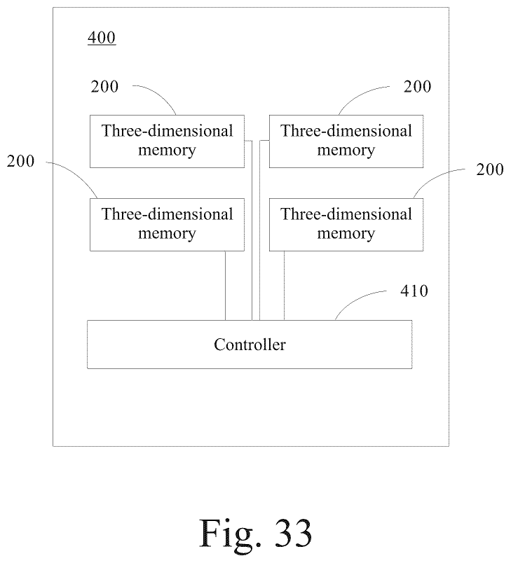

FIG. 32 is a block diagram of a memory system according to some implementations. FIG. 33 is a block of a memory system according to some other implementations.

Referring to FIGS. 32 and 33, some implementations of the present disclosure provide a memory system 400. The memory system 400 includes a controller 410 and a three-dimensional memory 200 as described in the above some implementations. The controller 410 may be coupled to the three-dimensional memory 200 to control the three-dimensional memory 200 to store data.

In some implementations, the memory system 400 may be integrated into various storage devices such as being included in the same package (such as Universal Flash Storage (UFS) package or Embedded Multi Media Card (eMMC) package). That is, the memory system 400 may be applied to and packaged in different types of electronic products such as a mobile phone (e.g., a cell phone), a desktop computer, a tablet, a notebook computer, a server, an on-vehicle device, a gaming console, a printer, a positioning device, a wearable device, a smart sensor, a mobile power source, a virtual reality (VR) device, an argument reality (AR) device, or any other suitable electronic devices having a memory therein.

In some implementations, referring to FIG. 32, the memory system 400 includes a controller 410 and a three-dimensional memory 200 and may be integrated in a memory card.

In some implementations, the memory card includes any one of a PC card (PCMCIA, Personal Computer Memory Card International Association), a Compact Flash (CF) card, a Smart Media (SM) card, a memory stick, a Multimedia Card (MMC), a Secure Digital Memory Card (SD) or a UFS.

In some other implementations, referring to FIG. 33, the memory system 400 includes a controller 410 and a plurality of three-dimensional memories 200 and is integrated in a solid-state drive (SSD).

In the memory system 400, in some implementations, the controller 410 may be configured to operate in low duty cycle environment, such as SD cards, CF cards, Universal Serial Bus (USB) flash drives, or other media used in electronic devices such as personal calculators, digital cameras and mobile phones.

In some other implementations, the controller 410 may be configured to operate in high duty cycle environment SSDs or eMMCs that are used as data stores and enterprise memory arrays of the mobile devices such as smart phones, tablet computers, and notebook computers.

In some implementations, the controller 410 may be configured to manage the data stored in three-dimensional memory 200 and communicate with external devices (such as a host). In some implementations, the controller 410 may be configured to control operations of the three-dimensional memory 200, such as read, erase, and program operations. In some implementations, the controller 410 may also be configured to manage various functions with respect to the data stored or to be stored in the memory 200 including at least one of bad-block management, garbage collection, logical-to-physical address conversion, wear leveling, etc. In some implementations, the controller 410 is further configured to process error correction codes with respect to the data read from or written to the three-dimensional memory 200.

Of course, any other suitable functions may be performed by the controller 410 as well, for example, formatting the three-dimensional memory 200. For example, the controller 410 may communicate with an external equipment such as a host via at least one of various interface protocols.

It is to be noted that the interface protocols include at least one of USB protocol, MMC protocol, peripheral component interconnection (PCI) protocol, PCI-express (PCI-E) protocol, advanced technology attachment (ATA) protocol, serial-ATA protocol, parallel-ATA protocol, small computer small interface (SCSI) protocol, enhanced small disk interface (ESDI) protocol, integrated drive electronics (IDE) protocol and Firewire protocol.

Some implementations of the present disclosure further provide an electronic apparatus. The electronic apparatus may be any one of a mobile phone, a desktop computer, a tablet computer, a notebook computer, a server, an on-vehicle device, a wearable device such as a smart watch, a smart bracelet and a pair of smart glasses, a mobile power source, a game console, a digital multimedia player, etc.

The electronic apparatus may include the memory system 400 as described above, and may further include at least one of a central processing unit and a cache.

The above-description provides only some example implementations of the present disclosure. The scope of the present disclosure is not limited thereto. Variations and substitutions that easily occur to any one skilled in the art in the technical scope disclosed by the present disclosure should be encompassed in the scope of the present disclosure. Therefore, the scope of the present disclosure should be determined by the scope of the claims.

What is claimed is:

1. A semiconductor structure, comprising:
a semiconductor layer;
a first stack structure disposed on the semiconductor layer and comprising a plurality of first insulating layers and a plurality of gate line layers disposed alternatively;
a second stack structure disposed on a side of the first stack structure away from the semiconductor layer and comprising at least one select gate line layer;
a gate line isolation structure penetrating through the first stack structure and the second stack structure in a direction perpendicular to the semiconductor layer; and
a first dielectric layer disposed on a side of the second stack structure away from the semiconductor layer and in contact with the gate line isolation structure, the first dielectric layer covering at least part of a surface of the gate line isolation structure away from the semiconductor layer.

2. The semiconductor structure of claim 1, further comprising:
a first channel structure penetrating through the first stack structure;
a second channel structure penetrating through the second stack structure and connected with the first channel structure;
a second dielectric layer disposed on a side of the first dielectric layer away from the semiconductor layer; and
a first conductive post penetrating through the second dielectric layer and the first dielectric layer and connected with the second channel structure.

3. The semiconductor structure of claim 2, further comprising:
a storage region; and
a connection region,
wherein the gate line isolation structure includes a first part located in the storage region, and
wherein the first dielectric layer is located in the storage region, the first dielectric layer is in contact with the first part, and the first dielectric layer covers a surface of the first part away from the semiconductor layer.

4. The semiconductor structure of claim 3, further comprising:
a second conductive post located in the connection region,
wherein the second conductive post penetrates through the second dielectric layer, the second stack structure, and a part of the first stack structure, and
wherein the second conductive post is connected with the gate line layer.

5. The semiconductor structure of claim 4, further comprising:
a third conductive post penetrating through the second dielectric layer and the first dielectric layer, the third conductive post being connected with the select gate line layer,
wherein the first dielectric layer surrounds the third conductive post and is in contact with the third conductive post, or
wherein there is a first spacing between the first dielectric layer and the third conductive post with a part of the second dielectric layer filled in the first spacing.

6. The semiconductor structure of claim 2, further comprising:
a storage region; and
a connection region,
wherein the first dielectric layer is located in the storage region and the connection region, and
wherein the first dielectric layer covers a surface of the gate line isolation structure away from the semiconductor layer.

7. The semiconductor structure of claim 6, further comprising:
a second conductive post located in the connection region, the second conductive post penetrating through the second dielectric layer, the first dielectric layer, the second stack structure, and a part of the first stack structure, and the second conductive post being connected with the gate line layer,
wherein the first dielectric layer further surrounds the second conductive post and is in contact with the second conductive post.

8. The semiconductor structure of claim 7, further comprising:
a third conductive post penetrating through the second dielectric layer and the first dielectric layer and connected with the select gate line layer,
wherein the first dielectric layer surrounds the third conductive post and is in contact with the third conductive post.

9. The semiconductor structure of claim 2, wherein the first dielectric layer and the second dielectric layer have different etch selection ratios under same etch conditions.

10. The semiconductor structure of claim 1, wherein a sidewall of the gate line isolation structure is in contact with the select gate lines.

11. The semiconductor structure of claim 1, wherein the second stack structure further comprises:
a third dielectric layer disposed between the select gate line layer and the first dielectric layer and having a etch selection ratio different from that of the first dielectric layer under same etch conditions.

12. A method of fabricating a semiconductor structure, comprising:
forming a first stack structure and a second stack structure on a substrate, the first stack structure comprising a plurality of first insulating layers and a plurality of gate line layers disposed alternatively, and the second stack structure comprising at least one select gate line layer;
forming a gate line isolation structure penetrating through the first stack structure and the second stack structure; and
forming an initial first dielectric layer on sides of the second stack structure and the gate line isolation structure away from the substrate, the initial first dielectric layer covering surfaces of the second stack structure and the gate line isolation structure away from the substrate.

13. The method of claim 12, wherein:
the semiconductor structure comprises a storage region and a connection region,
the initial first dielectric layer comprises a third part located in the storage region and a fourth part located in the connection region, and
after the forming the initial first dielectric layer, the method further comprises:
patterning the initial first dielectric layer to remove the fourth part of the initial first dielectric layer; and
forming a first avoiding hole in the third part of the initial first dielectric layer with a spacing between the first avoiding hole and the gate line isolation structure.

14. The method of claim 13, wherein:
before the forming the gate line isolation structure, the method further comprises:
forming a first channel structure penetrating through the first stack structure and a second channel structure penetrating the second stack structure and connected with the first channel structure, and
after the patterning the initial first dielectric layer, the method further comprises:
forming a second dielectric layer on sides of the initial first dielectric layer and the second stack structure away from the substrate;
forming a first contact hole on the second dielectric layer, the first contact hole penetrating through the second dielectric layer and stopping at the third part of the initial first dielectric layer;
extending the first contact hole such that the first contact hole penetrates through the initial first dielectric layer and exposes a surface of the second channel structure away from the substrate; and
forming a first conductive post in the first contact hole, the first conductive post being connected with the second channel structure.

15. The method of claim 14, wherein:
at the same time as forming the first contact hole on the second dielectric layer, the method further comprises:
forming a second contact hole and a third contact hole, wherein the second contact hole is located in the connection region, wherein the second contact hole penetrates through the second dielectric layer, the second stack structure and a part of the first stack structure, wherein the second contact hole exposes one of the gate line layers, and wherein the third contact hole penetrates through the second dielectric layer and the first avoiding hole and exposes a part of the select gate line layer; and
at the same time as forming the first conductive post in the first contact hole, the method further comprises:
forming a second conductive post in the second contact hole and forming a third conductive post in the third contact hole, the second conductive post being connected with the gate line layer, and the third conductive post being connected with the select gate line layer.

16. The method of claim 14, wherein between the extending the first contact hole such that the first contact hole penetrates through the initial first dielectric layer and forming the first conductive post in the first contact hole, the method further comprises:
forming a second contact hole and a third contact hole synchronously, the second contact hole being located in the connection region, the second contact hole penetrating through the second dielectric layer, the second stack structure, and a part of the first stack structure, the second contact hole exposing one of the gate line layers, the third contact hole penetrating through the second dielectric layer and the first avoiding hole, and the third contact hole exposing the select gate line layer; and
forming a second conductive post in the second contact hole and forming a third conductive post in the third contact hole, the second conductive post being connected with the gate line layer, and the third conductive post being connected with the select gate line layer.

17. The method of claim 12, wherein after the forming the initial first dielectric layer, the method further comprises:
forming a first channel structure penetrating through the first stack structure and a second channel structure penetrating the second stack structure and connected with the first channel structure;
forming a second dielectric layer on a side of the initial first dielectric layer away from the substrate;
forming a first contact hole on the second dielectric layer, the first contact hole penetrating through the second dielectric layer and stopping at the initial first dielectric layer;
extending the first contact hole such that the first contact hole penetrates through the initial first dielectric layer and exposes a surface of the second channel structure away from the substrate; and
forming a first conductive post in the first contact hole, the first conductive post being connected with the second channel structure.

18. The method of claim 17, wherein between the extending the first contact hole and forming the first conductive post in the first contact hole, the method further comprises:
forming a third contact hole that penetrates through the second dielectric layer and the initial first dielectric layer and exposes the select gate line layer; and
forming a second contact hole, wherein the second contact hole is located in a connection region, penetrates through the second dielectric layer, the initial first dielectric layer, the second stack structure and a part of the first stack structure, and exposes one of the gate line layers,
wherein an order of the forming the third contact hole and the forming the second contact hole is interchangeable.

19. The method of claim 17, wherein:
between the extending the first contact hole and forming the first conductive post in the first contact hole, the method further comprises:
forming a second contact hole and a third contact hole at a same time, the second contact hole being located in a connection region, the second contact hole penetrating through the second dielectric layer, the initial first dielectric layer, the second stack structure, and a part of the first stack structure, the second contact hole exposing one of the gate line layers, the third contact hole penetrating through the second dielectric layer and the first avoiding hole, and the third contact hole exposing a part of the select gate line layer, and
in a process of forming the first conductive post in the first contact hole, the method further comprises:
forming a second conductive post in the second contact hole, and forming a third conductive post in the third contact hole; wherein the second conductive post is connected with the gate line layer, and the third conductive post is connected with the select gate line layer.

20. A three-dimensional memory, comprising:
a semiconductor structure, comprising:
a semiconductor layer;
a first stack structure disposed on the semiconductor layer and comprising a plurality of first insulating layers and a plurality of gate line layers disposed alternatively;
a second stack structure disposed on a side of the first stack structure away from the semiconductor layer and comprising at least one select gate line layer;
a gate line isolation structure penetrating through the first stack structure and the second stack structure in a direction perpendicular to the semiconductor layer; and
a first dielectric layer disposed on a side of the second stack structure away from the semiconductor layer and being in contact with the gate line isolation structure, the first dielectric layer covering at least part of a surface of the gate line isolation structure away from the semiconductor layer; and
a peripheral device connected with the semiconductor structure.
